(19) United States
(12) Patent Application Publication
(10) Pub. No.: US 2012/0061652 A1
(43) Pub. Date: Mar. 15, 2012

(54) SEMICONDUCTOR DEVICE AND LIGHT-EMITTING DEVICE, AND MANUFACTUIRNG METHOD THEREOF

(75) Inventors: Nozomu Sugisawa, Isehara (JP); Kaoru Hatano, Atsugi (JP); Satoshi Seo, Sagamihara (JP)

(73) Assignee: SEMICONDUCTOR ENERGY LABORATORY CO., LTD., Atsugi-shi (JP)

(21) Appl. No.: 13/228,899

(22) Filed: Sep. 9, 2011

(30) Foreign Application Priority Data
Sep. 10, 2010 (JP) 2010-203028

(51) Int. Cl. H01L 27/32

(52) U.S. Cl. 257/40; 257/E27.119

(57) ABSTRACT

In a semiconductor device including an organic layer containing a light-emitting substance between a first electrode connected to a source or drain electrode layer of an enhancement-type transistor that has a channel formation region using an oxide semiconductor and a second electrode overlapped with the first electrode, an active, electrically conductive material which produces a hydrogen ion or a hydrogen molecule by reducing an impurity including a hydrogen atom (e.g., moisture) is excluded from the second electrode. The semiconductor device including an oxide semiconductor is formed using especially an inert, electrically conductive material which hardly causes production a hydrogen ion or a hydrogen molecule by reacting with water. Specifically, the semiconductor device is formed using any of a metal, an alloy of metals, and a metal oxide each having a higher oxidation-reduction potential than the standard hydrogen electrode.

### BACKGROUND OF THE INVENTION

1. Field of the Invention

The present invention relates to a semiconductor device and a light-emitting device each using an oxide semiconductor and a manufacturing method thereof.

Note that the semiconductor device in this specification refers to all devices including a semiconductor element that can function by utilizing semiconductor characteristics; semiconductor circuits, light-emitting devices, display devices, and electronic devices are all semiconductor devices.

2. Description of the Related Art

A technique in which a transistor is formed using a semiconductor material such as amorphous silicon, polysilicon, or transferred single crystal silicon over a substrate having an insulating surface has been known. While a transistor including amorphous silicon has low field effect mobility, the transistor can be easily formed over a large-area glass substrate. On the other hand, while a transistor including polycrystalline silicon has relatively high field effect mobility, the transistor requires a crystallization step such as laser annealing and cannot necessarily be easily formed over a large-area glass substrate. Further, a transistor including single crystal silicon has excellent operation characteristics but cannot necessarily be easily formed over a large-area substrate.

On the other hand, transistors using an oxide semiconductor as a semiconductor material have attracted attention. For example, Patent Document 1 and Patent Document 2 disclose a technique in which a transistor is manufactured using zinc oxide or an In—Ga—Zn—O-based oxide semiconductor as a semiconductor material and such a transistor is used as a switching element or the like of an image display device.

A transistor with a channel formation region (also referred to as a channel region) using an oxide semiconductor can have higher field-effect mobility than a transistor including amorphous silicon. An oxide semiconductor film can be easily formed over a large-area glass substrate by a sputtering method or the like and can be formed at a temperature of lower than or equal to 300° C.; therefore, a fabrication process of the transistor including an oxide semiconductor is simpler than that of a transistor using polycrystalline silicon.

The transistors using an oxide semiconductor can be applied to, for example, transistors included in a switching element provided in a pixel portion or transistors included in a driver circuit portion in a display device. Note that a driver circuit of a display device includes, for example, a shift register circuit, a buffer circuit, or the like, and the shift register circuit and the buffer circuit further include a logic circuit. By applying the transistor using an oxide semiconductor to a logic circuit of a driver circuit, the driver circuit can be driven at higher speed than in the case where a transistor including amorphous silicon is applied.

In addition, the logic circuit can be formed with transistors all having the same conductivity type. By manufacturing a logic circuit using transistors all having the same conductivity type, a process can be simplified.

With the use of a glass substrate or a plastic substrate over which such a transistor using an oxide semiconductor is formed, provision of display devices such as a liquid crystal display, an electroluminescent display (also referred to as an EL display), and electronic paper has been considered.

### REFERENCE

[Patent Document 1] Japanese Published Patent Application No. 2007-123861
[Patent Document 2] Japanese Published Patent Application No. 2007-096055

### SUMMARY OF THE INVENTION

There is a problem in that a transistor that has a channel formation region using an oxide semiconductor, which is of an enhancement (also referred to as normally-off) type, has changed into a depletion (also referred to as normally-on) type due to the use. A change of a transistor using an oxide semiconductor into a depletion type over time, which is a problem impairing the reliability of the semiconductor device, occurs particularly in a semiconductor device including an organic layer containing a light-emitting substance between a first electrode connected to a source electrode layer or a drain electrode layer of the enhancement-type transistor that has a channel formation region using an oxide semiconductor and a second electrode overlapped with the first electrode.

The present invention is made in view of the foregoing technical background. Therefore, an object of the present invention is to provide a highly reliable semiconductor device using an oxide semiconductor. Another object of the present invention is to provide a highly reliable light-emitting device using an oxide semiconductor.

In order to achieve the above objects, the present invention focuses on an active substance included in a semiconductor device using an oxide semiconductor, and specifically an active, electrically conductive material that is present in the semiconductor device using an oxide semiconductor and produces a hydrogen ion or a hydrogen molecule by reducing an impurity including a hydrogen atom (e.g., moisture).

An impurity including a hydrogen atom remains in and/or enters a semiconductor device using an oxide semiconductor from the outside of the device. In particular, it is difficult to completely remove moisture from the semiconductor device and/or to completely prevent entry of moisture from the air. Therefore, an active, electrically conductive material that reduces moisture present in a semiconductor element or the semiconductor device reacts with moisture that remains in and/or enters the device from the outside thereof, leading to production of a hydrogen ion or a hydrogen molecule.

The hydrogen ion or hydrogen molecule produced in the semiconductor device is diffused into the semiconductor element or the semiconductor device and accordingly reaches the oxide semiconductor. The hydrogen ion or hydrogen molecule increases the carrier concentration of the oxide semiconductor to cause impairment of the characteristics of the semiconductor element using the oxide semiconductor, which results in loss of reliability of even the semiconductor device including the semiconductor element.

To solve the above problems, in a semiconductor device including an organic layer containing a light-emitting substance between a first electrode connected to a source electrode layer or a drain electrode layer of an enhancement-type transistor that has a channel formation region using an oxide semiconductor and a second electrode overlapped with the first electrode, an active, electrically conductive material which produces a hydrogen ion or a hydrogen molecule by reducing an impurity including a hydrogen atom (e.g., moisture) should be excluded from the second electrode. The semiconductor device including an oxide semiconductor should be formed using especially an inert, electrically conductive material which hardly causes production a hydrogen ion or a hydrogen molecule by reacting with water. Specifically, the semiconductor device should be formed using a metal having a higher oxidation-reduction potential than the standard hydrogen electrode, an alloy of metals each having a higher oxidation-reduction potential than the standard hydrogen electrode, or an electrically conductive metal oxide having a higher oxidation-reduction potential than the standard hydrogen electrode.

Specifically, one embodiment of the present invention is a semiconductor device including an enhancement-type transistor that has a channel formation region using an oxide semiconductor and a light-emitting element in which an organic layer containing a light-emitting substance is interposed between a first electrode and a second electrode. The first electrode is electrically connected to a source electrode layer or a drain electrode layer of the transistor. The second electrode contains a metal having a higher oxidation-reduction potential than the standard hydrogen electrode at an amount greater than or equal to 99 at % and less than 100 at %.

According to the above embodiment of the present invention, by use of a metal having a higher oxidation-reduction potential than the standard hydrogen electrode for the second electrode, the activity of the second electrode with respect to an impurity including a hydrogen atom can be reduced. This can suppress reaction between the second electrode and the impurity including a hydrogen atom that remains in the semiconductor device and/or enters the device from the outside thereof, thereby reducing the number of the produced hydrogen ions or hydrogen molecules. Consequently, the number of hydrogen ions or hydrogen molecules that reach the oxide semiconductor is reduced; thus, characteristics of a semiconductor element using an oxide semiconductor and the reliability of the semiconductor device including the semiconductor element can be enhanced.

Another embodiment of the present invention is a semiconductor device including an enhancement-type transistor that has a channel formation region using an oxide semiconductor and a light-emitting element in which an organic layer containing a light-emitting substance is interposed between a first electrode and a second electrode. The first electrode is electrically connected to a source electrode layer or a drain electrode layer of the transistor. The second electrode contains an electrically conductive metal oxide having a higher oxidation-reduction potential than the standard hydrogen electrode.

According to the above embodiment of the present invention, by use of an electrically conductive metal that hardly reduced moisture for the second electrode, the activity of the second electrode with respect to an impurity including a hydrogen atom can be reduced. This can suppress reaction between the second electrode and the impurity including a hydrogen atom that remains in the semiconductor device and/or enters the device from the outside thereof, thereby reducing the number of the produced hydrogen ions or hydrogen molecules. Consequently, the number of hydrogen ions or hydrogen molecules that reach the oxide semiconductor is reduced; thus, characteristics of a semiconductor element using an oxide semiconductor and the reliability of the semiconductor device including the semiconductor element can be enhanced.

Another embodiment of the present invention is a semiconductor device including an enhancement-type transistor that has a channel formation region using an oxide semiconductor and a light-emitting element in which an organic layer containing a light-emitting substance is interposed between a first electrode and a second electrode. The first electrode is electrically connected to a source electrode layer or a drain electrode layer of the transistor. A layer containing a metal having a higher oxidation-reduction potential than the standard hydrogen electrode at an amount greater than or equal to 99 at % and less than 100 at % and a layer containing an electrically conductive metal oxide having a higher oxidation-reduction potential than the standard hydrogen electrode are stacked in the second electrode.

According to the above embodiment of the present invention, the activity of the second electrode with respect to an impurity including a hydrogen atom can be reduced. This can suppress reaction between the second electrode and the impurity including a hydrogen atom that remains in the semiconductor device and/or enters the device from the outside thereof, thereby reducing the number of the produced hydrogen ions or hydrogen molecules. Consequently, the number of hydrogen ions or hydrogen molecules that reach the oxide semiconductor is reduced; thus, characteristics of a semiconductor element using an oxide semiconductor and the reliability of the semiconductor device including the semiconductor element can be enhanced.

The second electrode can be used as a reflective electrode which reflects light emitted from the light-emitting element, by including the metal having a higher oxidation-reduction potential than the standard hydrogen electrode.

Another embodiment of the present invention is any of the above semiconductor devices including a charge generation layer in contact with the second electrode.

According to the above embodiment of the present invention, driving voltage of the light-emitting element can be reduced regardless of the work function of the second electrode. Consequently, it is possible not only to increase characteristics of the semiconductor element using an oxide semiconductor and reliability of the semiconductor device including the semiconductor element but also to reduce power consumption of the semiconductor device.

Another embodiment of the present invention is any of the above semiconductor devices containing an alkali metal and/or an alkaline earth metal at an amount greater than or equal to 4.1×10¹⁴ atoms/cm² and less than or equal to 4.5×10¹⁵ atoms/cm² per unit emission area.

According to the above embodiment of the present invention, although the alkali metal and/or the alkaline earth metal has high activity with respect to an impurity including a hydrogen atom, the alkali metal and/or alkaline earth metal is/are used with a metal having a higher oxidation-reduction potential than the standard hydrogen electrode, an alloy having a higher oxidation-reduction potential than the standard hydrogen electrode, an electrically conductive metal oxide having a higher oxidation-reduction potential than the standard hydrogen electrode, or an organic substance and is/are contained at an amount greater than or equal to 4.1×10¹⁴ atoms/cm² and less than or equal to 4.5×10¹⁵ atoms/cm² per unit emission area of the light-emitting element; as far as under these conditions, driving voltage of the semiconductor element and power consumption of the semiconductor device can be reduced without impairment of characteristics of the semiconductor element using an oxide semiconductor and of reliability of the semiconductor device including the semiconductor element.

Another embodiment of the present invention is any of the above semiconductor devices in which the above enhancement-type transistor that has the channel formation region using the oxide semiconductor has a gate insulating film, a gate electrode on one side of the gate insulating film, an oxide semiconductor layer on the other side of the gate insulating film, and a source and drain electrode layers which are in contact with the oxide semiconductor layer and whose end portions are overlapped with the gate electrode. The gate electrode layer or the source and drain electrode layers include one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

The long-term reliability of the semiconductor device is improved by formation of the gate electrode layer or the source and drain electrode layers using one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode, for the enhancement-type transistor that has a channel formation region using an oxide semiconductor.

In this specification, in the case where a substance A is dispersed in a matrix formed with a substance B, the substance B forming the matrix is referred to as a host material, and the substance A dispersed in the matrix is referred to as a guest material. Note that the substance A and the substance B may each be a single substance or a mixture of two or more kinds of substances.

Note that in this specification, a light-emitting device means an image display device, a light-emitting device, or a light source (including a lighting device). In addition, the light-emitting device includes any of the following modules in its category: a module in which a connector such as an FPC (flexible printed circuit), a TAB (tape automated bonding) tape, or a TCP (tape carrier package) is attached to a light-emitting device; a module having a TAB tape or a TCP provided with a printed wiring board at the end thereof; and a module in which an IC (integrated circuit) is directly mounted by a COG (chip on glass) method on a substrate provided with a light-emitting element.

According to the present invention, a highly reliable semiconductor device using an oxide semiconductor can be provided. Further, a highly reliable light-emitting device using an oxide semiconductor can be provided.

### BRIEF DESCRIPTION OF THE DRAWINGS

FIGS. 1A to 1C each illustrate a semiconductor device according to an embodiment.

FIGS. 2A to 2E illustrate a structure of a transistor and a manufacturing method thereof according to an embodiment.

FIG. 3 illustrates a structure of a transistor according to an embodiment.

FIG. 4 illustrates a structure of a light-emitting element according to an embodiment.

FIG. 5 is an equivalent circuit diagram illustrating a configuration of a pixel according to an embodiment.

FIGS. 6A to 6C are cross-sectional views each illustrating a structure of a pixel according to an embodiment.

FIGS. 7A and 7B illustrate a structure of a light-emitting display device according to an embodiment.

FIGS. 8A and 8B each illustrate a structure of a light-emitting element according to an example.

FIGS. 9A to 9C illustrate display states of light-emitting display devices according to an example.

### DETAILED DESCRIPTION OF THE INVENTION

Embodiments will be described in detail with reference to the drawings. Note that the present invention is not limited to the following description, and it will be easily understood by those skilled in the art that various changes and modifications can be made without departing from the spirit and scope of the present invention. Therefore, the present invention should not be construed as being limited to the description in the following embodiments. Note that in the structures of the present invention described below, the same portions or portions having similar functions are denoted by the same reference numerals in different drawings, and description of such portions is not repeated.

### Embodiment 1

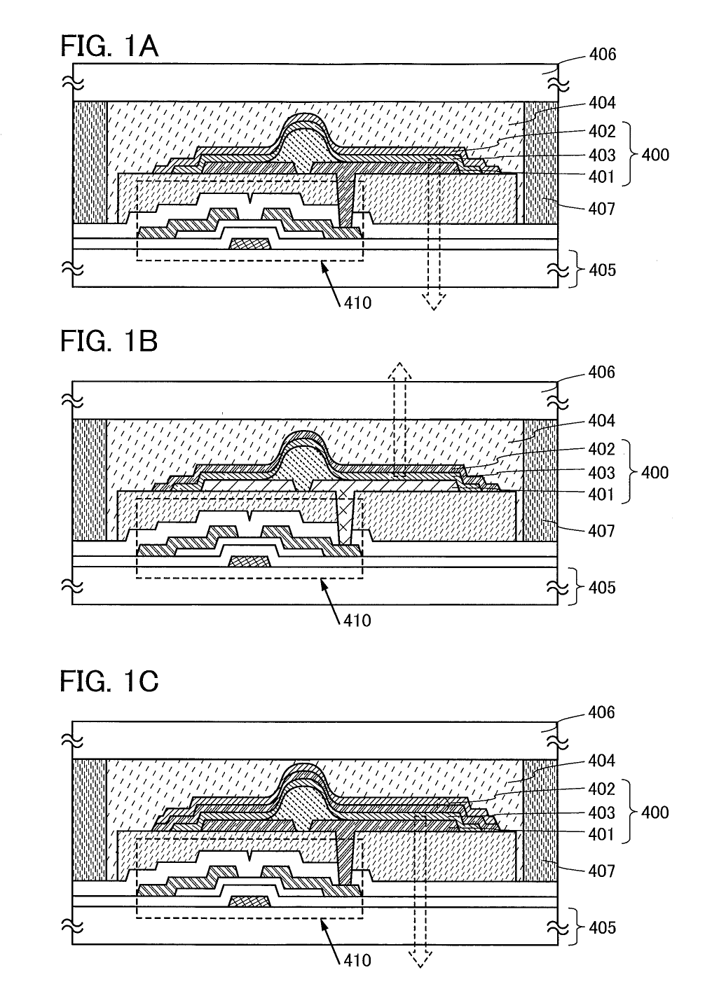

In this embodiment, a structure of a semiconductor device including a semiconductor element using an oxide semiconductor and a light-emitting element in which an organic layer containing a light-emitting substance is provided between a first electrode and a second electrode will be described with reference to FIGS. 1A to 1C. Note that because an inert, electrically conductive material is used for the second electrode of the light-emitting element given as an example in this embodiment, the reduction of an impurity including a hydrogen atom (e.g., moisture) and production of a hydrogen ion or a hydrogen molecule hardly occur.

The semiconductor device described in this embodiment is a light-emitting device having a transistor and the light-emitting element connected to the transistor. The light-emitting element can also be used for a pixel portion of the light-emitting display device by being provided in matrix arrangement.

In the semiconductor device given as an example in this embodiment, a transistor 410 and a light-emitting element 400 are provided over a substrate 405 having an insulating surface. The transistor 410, in which an oxide semiconductor is used for a channel formation region, performs enhancement operation. In the light-emitting element 400, an organic layer 403 containing a light-emitting substance is interposed between a first electrode 401 and a second electrode 402, and the first electrode is electrically connected to a source electrode layer or a drain electrode layer of the transistor. In addition, the transistor 410 and the light-emitting element 400 are sealed and insulated from an atmosphere containing an impurity including a hydrogen atom (e.g., moisture).

Note that, in the semiconductor device given as an example in this embodiment, the transistor 410 and the light-emitting element 400 are sealed together with a filler 404 between the substrate 405 and the sealing substrate 406 by a sealant 407 surrounding the transistor 410 and the light-emitting element 400. As the filler 404, an inert gas of nitrogen, argon, or the like, from which an impurity including a hydrogen atom (e.g., moisture) is removed, can be used.

The second electrode 402 of the light-emitting element 400 is formed using an inert, electrically conductive material which hardly causes reduction of an impurity including a hydrogen atom (e.g., moisture) and production of a hydrogen ion or a hydrogen molecule. Examples of the inert, electrically conductive material which hardly produces a hydrogen ion or a hydrogen molecule are a metal having a higher oxidation-reduction potential than the standard hydrogen electrode, an alloy of metals each having a higher oxidation-reduction potential than the standard hydrogen electrode, and an electrically conductive metal oxide having a higher oxidation-reduction potential than the standard hydrogen electrode. The second electrode 402 can be formed using a stack of electrically conductive layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

Examples of the metal having a higher oxidation-reduction potential than the standard hydrogen electrode are antimony (Sb), arsenic (As), bismuth (Bi), copper (Cu), tellurium (Te), mercury (Hg), silver (Ag), palladium (Pd), platinum (Pt), gold (Au), and the like. For the second electrode 402, such a metal should be used alone or an alloy thereof should be used. The reduction action by such a metal is weak, and an electrically conductive layer that contains the above metal at an amount greater than or equal to 99 at % and less than 100 at % becomes inert and hardly causes reduction of an impurity including a hydrogen atom (e.g., moisture) and production of a hydrogen ion or a hydrogen molecule.

Note that the second electrode 402 may be an alloy of metals each having a higher oxidation-reduction potential than the standard hydrogen electrode. Especially a silver-palladium (Ag—Pd) alloy or a silver-copper (Ag—Cu) alloy has high reflectivity with respect to visible light, and is suitable for the reflective electrode accordingly (see FIG. 1A).

Further, the above metal can also be used as an electrically conductive film that transmits visible light by being formed into a film that is sufficiently thin to transmit light (preferably about 5 nm to 30 nm).

Examples of the electrically conductive metal oxide having a higher oxidation-reduction potential than the standard hydrogen electrode are indium oxide containing tungsten oxide (IWO), indium zinc oxide containing tungsten oxide (IWZO), indium oxide containing titanium oxide (Ti—InO), indium tin oxide containing titanium oxide (Ti—ITO), indium tin oxide (ITO), indium zinc oxide (IZO), indium tin oxide to which silicon oxide is added (ITSO), tin oxide (SnOx), tungsten oxide (WOx), titanium oxide (TiOx), and the like. The reduction action by such an electrically conductive metal oxide having a higher oxidation-reduction potential than the standard hydrogen electrode is weak, and the metal oxide hardly causes reduction of an impurity including a hydrogen atom (e.g., moisture) and production of a hydrogen ion or a hydrogen molecule.

When an electrically conductive metal oxide layer that has a higher oxidation-reduction potential than the standard hydrogen electrode and transmits visible light is used especially for the second electrode 402, light emission from the organic layer 403 containing a light-emitting substance can be extracted toward the second electrode 402 (see FIG. 1B).

A stack of layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode can also be used to form the second electrode 402. For example, an electrically conductive metal oxide layer that has a higher oxidation-reduction potential than the standard hydrogen electrode and transmits visible light is formed between the organic layer 403 containing a light-emitting substance and a metal layer that has high reflectivity and a higher oxidation-reduction potential than the standard hydrogen electrode, so that the distance between the organic layer 403 containing a light-emitting substance and a reflective electrode can be adjusted. By adjustment of the distance between them, the light extraction efficiency and emission spectrum of the light-emitting element 400 can be changed. (See FIG. 1C)

Further, when a metal layer having a higher oxidation-reduction potential than the standard hydrogen electrode is formed between the organic layer 403 containing a light-emitting substance and an electrically conductive metal oxide layer that has a higher oxidation-reduction potential than the standard hydrogen electrode and transmits visible light, the organic layer 403 containing a light-emitting substance can be prevented from being damaged at the time of the formation of the electrically conductive metal oxide layer having a higher oxidation-reduction potential than the standard hydrogen electrode using a sputtering method.

In the semiconductor element given as an example in this embodiment, an inert, electrically conductive material is used for the second electrode. Consequently, it is possible to suppress a phenomenon in which moisture that remains in the semiconductor device and/or enters the device from the outside thereof reacts with an electrically conductive material to produce a hydrogen ion or a hydrogen molecule.

Production of a hydrogen ion or a hydrogen molecule which increases the carrier concentration in the oxide semiconductor is suppressed, and accordingly, a semiconductor device having excellent reliability can be provided using the oxide semiconductor. Alternatively, a light-emitting device having excellent reliability can be provided using the oxide semiconductor.

This embodiment can be combined with any of the other embodiments in this specification as appropriate.

### Embodiment 2

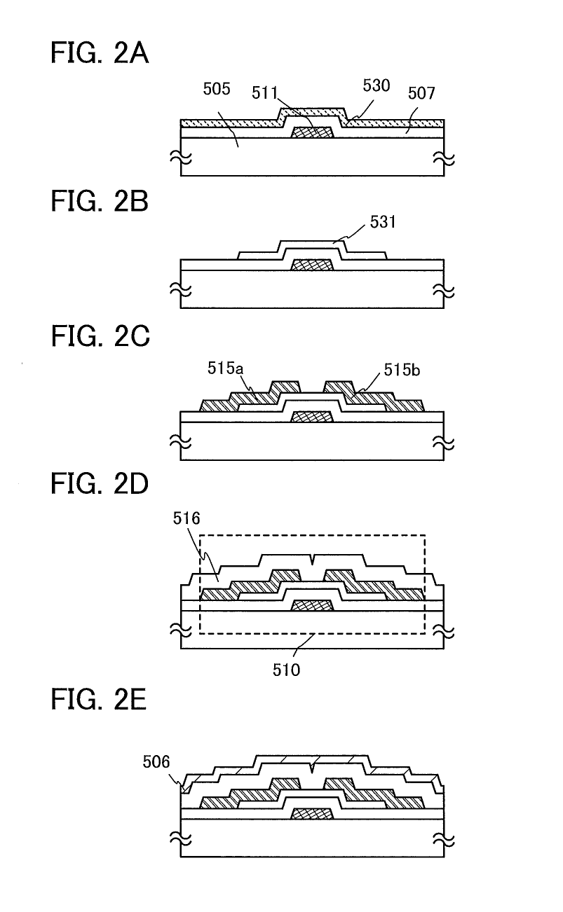

In this embodiment, a transistor that has a channel formation region using an oxide semiconductor will be described. The enhancement-type transistor that has a channel formation region using an oxide semiconductor has a gate electrode on one side of a gate insulating film, an oxide semiconductor layer on the other side of the gate insulating film, and a source and drain electrode layers which are in contact with the oxide semiconductor layer and whose end portions are overlapped with the gate electrode. In this embodiment, as an example of the enhancement-type transistor that has a channel formation region using an oxide semiconductor, a structure of an inverted staggered transistor using an oxide semiconductor and a manufacturing method thereof will be described with reference to FIGS. 2A to 2E. Note that the transistor is not limited to an inverted staggered transistor, and the transistor may be a staggered transistor, a coplanar transistor, or an inverted coplanar transistor and may have a channel-etched structure or a channel protective structure.

Note that the transistor described in this embodiment can be applied to the semiconductor device described in Embodiment 1.

### (First Step: Formation of Transistor)

FIGS. 2A to 2E show an example of a cross-sectional structure of a transistor that has a channel formation region using an oxide semiconductor. The transistor illustrated in FIGS. 2A to 2E is a bottom-gate inverted staggered transistor.

The oxide semiconductor used for the semiconductor layer in this embodiment is made to be an i-type (intrinsic) oxide semiconductor or made to be extremely close to an i-type (intrinsic) oxide semiconductor, by removal of hydrogen, which is an n-type impurity, from the oxide semiconductor and by higher purification such that impurities which are not main components of the oxide semiconductor are contained as little as possible.

Note that the highly purified oxide semiconductor includes extremely few carriers, and the carrier concentration is less than 1×10¹⁴/cm³, preferably less than 1×10¹²/cm³, more preferably less than 1×10¹¹/cm³. Further, such few carriers make a current in an off state (an off-state current) sufficiently small.

Specifically, in the transistor including the above oxide semiconductor layer, the leakage current density (off-state current density) per micrometer of a channel width between the source and drain in an off state can be less than or equal to 100 zA/μm (1×10⁻¹⁹ A/μm), preferably less than or equal to 10 zA/μm (1×10⁻²⁰ A/μm), and further preferably less than or equal to 1 zA/μm (1×10⁻²¹ A/μm) with a voltage between the source and drain of 3.5 V and under the temperature conditions at the time of use (e.g., 25° C.).

Further, in the transistor including the highly purified oxide semiconductor layer, the temperature dependence of on-state current is hardly observed, and the off-state current remains extremely low even in a high temperature state.

A process of fabricating the transistor that has a channel formation region using an oxide semiconductor over a substrate 505 is described below with reference to FIGS. 2A to 2E. Note that a resist mask may be formed by an inkjet method. No photomask is used in formation of the resist mask by an inkjet method; thus, manufacturing cost can be reduced.

### [1-1. Substrate Having Insulating Surface]

First, an electrically conductive film is formed over the substrate 505 having the insulating surface, and then a gate electrode layer 511 is formed through a first photolithography step.

There is no significant limitation on the substrate 505 as far as it has the insulating surface and a gas barrier property with respect to water vapor and a hydrogen gas; however, in the case where heat treatment is performed in a subsequent step, the substrate 505 should have at least heat resistance high enough to withstand the heat temperature. For example, a glass substrate of barium borosilicate glass, aluminoborosilicate glass, or the like, a quartz substrate, a sapphire substrate, a ceramic substrate, or the like can be used. Alternatively, a metal substrate containing stainless steel or a semiconductor substrate having an insulating film formed on its surface may be used. A flexible substrate that is formed with synthetic resin such as plastics can be used as far as it can withstand processing temperature in a fabrication process, although the upper temperature limit of such a substrate is generally lower than those of the above substrates. Note that the surface of the substrate 505 may be planarized by polishing such as a CMP method.

In this embodiment, a glass substrate is used as the substrate 505 having the insulating surface.

Note that an insulating layer serving as a base may be provided between the substrate 505 and the gate electrode layer 511. The insulating layer has a function of preventing diffusion of an impurity element from the substrate 505, and can be formed to have a stacked-layer structure of one or more films selected from a silicon nitride film, a silicon oxide film, a silicon nitride oxide film, a silicon oxynitride film, and the like.

### [1-2. Gate Electrode Layer]

Further, for the gate electrode layer 511, a metal material such as molybdenum, titanium, chromium, tantalum, tungsten, neodymium, or scandium, or an alloy material which contains any of these materials as its main component is used as a material to form a single layer or stacked layers. Note that aluminum or copper can also be used as such a metal material if it can withstand the temperature of heat treatment to be performed in a subsequent process. Aluminum or copper is preferably combined with a refractory metal material so as to avoid a problem of heat resistance or corrosivity. As the refractory metal material, molybdenum, titanium, chromium, tantalum, tungsten, neodymium, scandium, or the like can be used.

Through the fabrication process, a surface of the gate electrode layer 511 is stabilized by forming the passive state, for example. Further, the gate electrode layer 511 is particularly preferably formed using one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode so that the long-term reliability of the semiconductor device is improved.

### [1-3. Gate Insulating Layer]

Next, a gate insulating layer 507 is formed over the gate electrode layer 511. The gate insulating layer 507 can be formed using a plasma CVD method, a sputtering method, or the like. Further, the gate insulating layer 507 can be formed as a single layer or a stacked layers of one or more films selected from a silicon oxide film, a silicon nitride film, a silicon oxynitride film, a silicon nitride oxide film, an aluminum oxide film, an aluminum nitride film, an aluminum oxynitride film, an aluminum nitride oxide film, a hafnium oxide film, a tantalum oxide film, a gallium oxide film, and the like.

For the oxide semiconductor in this embodiment, the i-type or substantially i-type oxide semiconductor (highly purified oxide semiconductor), from which an impurity is removed, is used. Such a highly purified oxide semiconductor is extremely sensitive to an interface state and interface charge; thus, an interface between the oxide semiconductor layer and the gate insulating layer is important. For that reason, the gate insulating layer in contact with the highly purified oxide semiconductor should have higher quality.

For example, it is preferable to use high-density plasma CVD using microwaves (e.g., with a frequency of 2.45 GHz), which enables formation of a high-quality insulating layer that is dense and has high withstand voltage. This is because the highly purified oxide semiconductor and the high-quality gate insulating layer are in close contact with each other so that the interface state density can be reduced and favorable interface characteristics can be obtained.

Needless to say, another film formation method such as a sputtering method or a plasma CVD method can be employed as far as the method enables formation of a good-quality insulating layer as the gate insulating layer. The gate insulating layer may be an insulating layer whose film quality and whose characteristic in the interface with the oxide semiconductor can be improved by heat treatment after the formation, and may be any layer as far as it can reduce the interface state density between the insulating layer and the oxide semiconductor and can form a favorable interface as well as have favorable film quality as the gate insulating layer.

Note that the gate insulating layer 507 is in contact with an oxide semiconductor layer to be formed later. Since diffusion of hydrogen in the oxide semiconductor impairs the semiconductor characteristics, it is preferable that the gate insulating layer 507 do not contain hydrogen, hydroxyl, and moisture. In order that the gate insulating layer 507 and an oxide semiconductor film 530 be prevented from containing hydrogen, hydroxyl, and moisture as much as possible, pretreatment is preferably performed as follows before formation of the oxide semiconductor film 530: the substrate 505 provided with the gate electrode layer 511 or the substrate 505 provided with layers up to and including the gate electrode layer 507 is preheated in a preheating chamber of a sputtering apparatus so that impurities such as hydrogen or moisture adsorbed on the substrate 505 is eliminated; and then exhaustion is performed. The temperature for the preheating is higher than or equal to 100° C. and lower than or equal to 400° C., preferably higher than or equal to 150° C. and lower than or equal to 300° C. Note that as an exhaustion unit provided in the preheating chamber, a cryopump is preferable. Note also that this preheating treatment can be omitted. Further, in the same way, this preheating treatment may be performed on the substrate 505 over which layers up to and including a source electrode layer 515a and a drain electrode layer 515b are formed before formation of a first insulating layer 516.

### [1-4. Oxide Semiconductor Layer]

Next, over the gate insulating layer 507, the oxide semiconductor film 530 having a thickness greater than or equal to 2 nm and less than or equal to 200 nm, preferably greater than or equal to 5 nm and less than or equal to 30 nm is formed (see FIG. 2A).

The oxide semiconductor film is formed using an oxide semiconductor as a target by a sputtering method. Moreover, the oxide semiconductor film can be formed under a rare gas (e.g., argon) atmosphere, an oxygen atmosphere, or a mixed atmosphere of a rare gas (e.g., argon) and oxygen by a sputtering method.

Note that before the oxide semiconductor film 530 is formed by a sputtering method, powdery substances (also referred to as particles or dust) attached to a surface of the gate insulating layer 507 are preferably removed by reverse sputtering in which plasma is generated by introduction of an argon gas. The reverse sputtering refers to a method in which an RF power supply is used for application of a voltage to a substrate side under an argon atmosphere and plasma is generated around the substrate to modify a surface. Note that instead of an argon atmosphere, nitrogen, helium, oxygen, or the like may be used.

As the oxide semiconductor used for the oxide semiconductor film 530, any of the following metal oxides can be used: a four-component metal oxide such as an In—Sn—Ga—Zn—O-based oxide semiconductor; three-component metal oxides such as an In—Ga—Zn—O-based oxide semiconductor, an In—Sn—Zn—O-based oxide semiconductor, an In—Al—Zn—O-based oxide semiconductor, a Sn—Ga—Zn—O-based oxide semiconductor, an Al—Ga—Zn—O-based oxide semiconductor, and a Sn—Al—Zn—O-based oxide semiconductor; two-component metal oxides such as an In—Zn—O-based oxide semiconductor, a Sn—Zn—O-based oxide semiconductor, an Al—Zn—O-based oxide semiconductor, and an In—Ga—O-based oxide semiconductor; an In—O-based oxide semiconductor; a Sn—O-based oxide semiconductor; a Zn—O-based oxide semiconductor; and the like. Further, the above oxide semiconductor layer may contain silicon oxide. In the oxide semiconductor layer containing silicon oxide (SiOₓ (x>0)), which hinders crystallization, crystallization due to heat treatment after formation of the oxide semiconductor layer in the fabrication process can be suppressed. Note that the oxide semiconductor layer preferably exists in an amorphous state; however, the oxide semiconductor layer may be partly crystallized. In this specification, for example, an In—Ga—Zn—O-based oxide semiconductor means an oxide film containing indium (In), gallium (Ga), and zinc (Zn), and there is no particular limitation on the composition ratio. The In—Ga—Zn—O-based oxide semiconductor may contain an element other than In, Ga, and Zn.

In addition, for the oxide semiconductor film 530, a thin film of a material represented by the chemical formula, InMO₃(ZnO)ₘ (m>0), can be used. Here, M represents one or more metal elements selected from Ga, Al, Mn, and Co. For example, M can be Ga, Ga and Al, Ga and Mn, Ga and Co, or the like.

The oxide semiconductor preferably includes In, more preferably includes In and Ga. Dehydration or dehydrogenation is effective in making the oxide semiconductor layer become an i-type (intrinsic) oxide semiconductor. In this embodiment, the oxide semiconductor film 530 is formed using an In—Ga—Zn—O-based oxide semiconductor target by a sputtering method. A cross-sectional view of this stage corresponds to FIG. 2A.

The target used for formation of the oxide semiconductor film 530 by a sputtering method is, for example, an oxide target containing In₂O₃, Ga₂O₃, and ZnO at a composition ratio of 1:1:1 [molar ratio], so that an In—Ga—Zn—O film is formed. Without limitation to the material and composition of this target, for example, an oxide target containing In₂O₃, Ga₂O₃, and ZnO at 1:1:2 [molar ratio] or In₂O₃, Ga₂O₃, and ZnO at 1:1:4 [molar ratio] may be used.

Furthermore, the filling rate of the oxide target is greater than or equal to 90% and less than or equal to 100%, preferably greater than or equal to 95% and less than or equal to 99.9%. With use of the metal oxide target having a high filling rate, the oxide semiconductor film can be a dense film.

A high-purity gas from which impurities such as hydrogen, water, hydroxyl, or hydride is removed is preferably used as a sputtering gas used for the formation of the oxide semiconductor film 530.

The substrate is held in a film formation chamber in a reduced pressure state, and the substrate temperature is set to a temperature higher than or equal to 100° C. and lower than or equal to 600° C., preferably higher than or equal to 200° C. and lower than or equal to 400° C. By film formation performed while the substrate is heated, the concentration of impurities contained in the oxide semiconductor film formed can be reduced. In addition, damage by sputtering can be reduced. Then, the sputtering gas from which hydrogen and moisture have been removed is introduced into the film formation chamber while moisture remaining therein is removed, and the oxide semiconductor film 530 is formed over the substrate 505 with the use of the above target. In order to remove moisture remaining in the film formation chamber, an entrapment vacuum pump such as a cryopump, an ion pump, or a titanium sublimation pump is preferably used. The exhaustion unit may be a turbo pump provided with a cold trap. In the film formation chamber which is exhausted with the cryopump, a hydrogen atom, a compound containing a hydrogen atom, such as water (H₂O), (more preferably, also a compound containing a carbon atom), and the like are removed, so that the concentration of impurities contained in the oxide semiconductor film formed in the film formation chamber can be reduced.

The atmosphere for the sputtering method should be a rare gas (typically argon) atmosphere, an oxygen atmosphere, or a mixed atmosphere containing a rare gas and oxygen.

As examples of the film formation conditions, the distance between the substrate and the target is 100 mm, the pressure is 0.6 Pa, the direct-current (DC) power source is 0.5 kW, and the atmosphere is an oxygen atmosphere (the proportion of the oxygen flow rate is 100%). Note that a pulsed direct-current power source, with which powder substances (also referred to as particles or dust) that are generated in film formation can be reduced and the film thickness can be uniform, is preferably used.

It is preferable that impurities, for example, an alkali metal such as Li or Na and an alkaline earth metal such as Ca contained in the oxide semiconductor layer be reduced. Specifically, it is preferable that the concentration of Li be lower than or equal to 5×10¹⁵ cm⁻³, preferably lower than or equal to 1×10¹⁵ cm⁻³, and the concentration of K be lower than or equal to 5×10¹⁵ cm⁻³, preferably lower than or equal to 1×10¹⁵ cm⁻³ when detected by SIMS.

Alkali metals and alkaline earth metals are adverse impurities for the oxide semiconductor and are preferably contained as little as possible. Among alkali metals, especially Na is diffused into an oxide to become Na⁺ when an insulating film in contact with the oxide semiconductor is the oxide. In addition, a bond between metal and oxygen is cut or broken in the oxide semiconductor. Thus, transistor characteristics deteriorate (e.g., the transistor becomes normally-on (a threshold voltage shifts in the negative direction) or the mobility decreases). In addition, this also causes variation in the characteristics. Such a problem is significant especially in the case where the hydrogen concentration in the oxide semiconductor is sufficiently low. Therefore, the concentration of an alkali metal should be set to the above value in the case where the hydrogen concentration in the oxide semiconductor is lower than or equal to 5×10¹⁹ cm⁻³, particularly lower than or equal to 5×10¹⁸ cm⁻³.

Next, the oxide semiconductor film 530 is processed into an island-shaped oxide semiconductor layer in a second photolithography step.

In the case where a contact hole is formed in the gate insulating layer 507, a step of forming the contact hole can be performed at the same time as processing of the oxide semiconductor film 530.

Note that etching of the oxide semiconductor film 530 here may be dry etching or wet etching, or both dry etching and wet etching. As an etchant used for wet etching of the oxide semiconductor film 530, for example, a mixed solution of phosphoric acid, acetic acid, and nitric acid can be used. In addition, ITO07N (produced by KANTO CHEMICAL CO., INC.) may also be used.

As an etching gas used for dry etching, a gas containing chlorine (e.g., a chlorine-based gas such as chlorine (Cl₂), boron trichloride (BCl₃), silicon tetrachloride (SiCl₄), or carbon tetrachloride (CCl₄)) is preferable. Alternatively, a gas containing fluorine (a fluorine-based gas such as carbon tetrafluoride (CF₄), sulfur hexafluoride (SF₆), nitrogen trifluoride (NF₃), or trifluoromethane (CHF₃)), hydrogen bromide (HBr), oxygen (O₂), any of these gases to which a rare gas such as helium (He) or argon (Ar) is added, or the like can be used.

As the dry etching method, a parallel plate RIE (reactive ion etching) method or an ICP (inductively coupled plasma) etching method can be used. In order to etch the films into desired shapes, etching conditions (e.g., the amount of electric power applied to a coil-shaped electrode, the amount of electric power applied to an electrode on a substrate side, or the temperature of the electrode on the substrate side) are adjusted as appropriate.

Next, the oxide semiconductor layer is subjected to first heat treatment. The oxide semiconductor layer can be dehydrated or dehydrogenated through this first heat treatment. The temperature of the first heat treatment is higher than or equal to 250° C. and lower than or equal to 750° C., preferably higher than or equal to 400° C. and lower than the strain point of the substrate. For example, the heat treatment may be performed at 500° C. for about more than or equal to 3 minutes and less than or equal to 6 minutes. When using an RTA method for the heat treatment, dehydration or dehydrogenation can be performed in a short time, and therefore, the treatment can be performed even at a temperature higher than the strain point of the glass substrate.

Here, the substrate is introduced into an electric furnace which is a kind of heat treatment apparatus, and the heat treatment is performed on the oxide semiconductor layer at 450° C. for 1 hour, under a nitrogen atmosphere, and then an oxide semiconductor layer 531 is obtained while water or hydrogen is prevented from entering the oxide semiconductor layer without exposure to the air (see FIG. 2B).

Further, a heat treatment apparatus used is not limited to the electric furnace, and a device for heating an object to be processed by heat conduction or heat radiation from a heating element such as a resistance heating element may be used. For example, an RTA (rapid thermal anneal) apparatus such as a GRTA (gas rapid thermal anneal) apparatus or an LRTA (lamp rapid thermal anneal) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the high-temperature gas, an inert gas which does not react with an object to be processed by heat treatment, for example, nitrogen or a rare gas such as argon is used.

For example, as the first heat treatment, GRTA, by which the substrate is moved into an inert gas heated to high temperature as high as 650° C. to 700° C., heated for several minutes, and moved out of the inert gas heated to high temperature, may be performed.

Note that in the first heat treatment, it is preferable that water, hydrogen, and the like be not contained in the atmosphere of nitrogen or a rare gas such as helium, neon, or argon. Alternatively, it is preferable that the purity of nitrogen or the rare gas such as helium, neon, or argon which is introduced into the heat treatment apparatus be set to be higher than or equal to 6N (99.9999%), more preferably higher than or equal to 7N (99.99999%) (that is, the concentration of impurities is lower than or equal to 1 ppm, preferably lower than or equal to 0.1 ppm).

In addition, after the oxide semiconductor layer is heated by the first heat treatment, a high-purity oxygen gas, a high-purity N₂O gas, or ultra-dry air (the amount of moisture is less than or equal to 20 ppm (−55° C. by conversion into a dew point), preferably less than or equal to 1 ppm, or more preferably less than or equal to 10 ppb, when measured with a dew point meter of a cavity ring down laser spectroscopy (CRDS) system) may be introduced into the same furnace. It is preferable that the oxygen gas and the N₂O gas do not include water, hydrogen, and the like. Alternatively, the purity of the oxygen gas or the N₂O gas that is introduced into the heat treatment apparatus is preferably higher than or equal to 6N, more preferably higher than or equal to 7N (i.e., the concentration of impurities in the oxygen gas or the N₂O gas is preferably lower than or equal to 1 ppm, more preferably lower than or equal to 0.1 ppm). By the action of the oxygen gas or the N₂O gas, oxygen, which is one of main components of the oxide semiconductor and has been reduced in the step of removal of impurities through the dehydration or the dehydrogenation, is supplied; thus, the oxide semiconductor layer is highly purified and made to be an electrically i-type (intrinsic).

The first heat treatment for the oxide semiconductor layer can also be performed on the oxide semiconductor film 530 which has not yet been processed into the island-shaped oxide semiconductor layer. In that case, the substrate is taken out from the heat treatment apparatus after the first heat treatment, and then a photolithography step is performed.

Note that the first heat treatment may be performed at either of the following timings without limitation to the above-described timing as far as it is performed after the oxide semiconductor layer is formed: after the source electrode layer and the drain electrode layer are formed over the oxide semiconductor layer; and after the insulating layer is formed over the source electrode layer and the drain electrode layer.

In the case where a contact hole is formed in the gate insulating layer 507, formation of the contact hole may be performed before or after the first heat treatment is performed on the oxide semiconductor film 530.

Through the above process, the concentration of hydrogen in the island-shaped oxide semiconductor layer can be reduced and the island-shaped oxide semiconductor layer can be highly purified. Accordingly, stabilization of the oxide semiconductor layer can be attempted. In addition, an oxide semiconductor layer with a wide band gap, in which carrier density is extremely low, can be formed by heat treatment at a temperature lower than or equal to the glass transition temperature. Accordingly, the transistor can be manufactured using a large-area substrate, so that the productivity can be increased. In addition, by use of the oxide semiconductor layer in which the hydrogen concentration is reduced and which is highly purified, a transistor with a high withstand voltage and an extremely small off-state current can be manufactured. The above heat treatment can be performed at any time as far as it is performed after the oxide semiconductor layer is formed.

In addition, the oxide semiconductor layer may be formed by film formation in two separate steps and heat treatment in two separate steps so that an oxide semiconductor layer having a crystal region with a large thickness (a single crystal region), i.e., a crystal region that is c-axis-aligned perpendicularly to a surface of the film can be formed regardless of whether a material of a base component is an oxide, a nitride, a metal, or the like. For example, a first oxide semiconductor film having a thickness greater than or equal to 3 nm and less than or equal to 15 nm is formed and then first heat treatment is performed at a temperature higher than or equal to 450° C. and lower than or equal to 850° C., preferably higher than or equal to 550° C. and lower than or equal to 750° C. under an atmosphere of nitrogen, oxygen, a rare gas, or dry air, so that a first oxide semiconductor film which includes a crystal region (including plate-like crystals) in a region including its surface is formed. Then, a second oxide semiconductor film which is thicker than the first oxide semiconductor film is formed and then second heat treatment is performed at a temperature higher than or equal to 450° C. and lower than or equal to 850° C., preferably higher than or equal to 600° C. and lower than or equal to 700° C., so that crystal growth proceeds upward with the use of the first oxide semiconductor film as a seed of the crystal growth, so that the whole second oxide semiconductor film is crystallized. In such a way, an oxide semiconductor layer which includes a thick crystal region may be formed.

### [1-5. Source Electrode Layer and Drain Electrode Layer]

Next, an electrically conductive film which serves as a source electrode layer and a drain electrode layer (including a wiring formed using the same layer as these layers) is formed over the gate insulating layer 507 and the oxide semiconductor layer 531. As the electrically conductive film used for the source electrode layer and the drain electrode layer, for example, a metal film including an element selected from Al, Cr, Cu, Ta, Ti, Mo, and W, an alloy or a metal nitride film including any of the above elements as its component (e.g., a titanium nitride film, a molybdenum nitride film, or a tungsten nitride film), or the like can be used. In addition, in order to avoid a problem of heat resistance or corrosivity, a structure in which a film of a metal such as Al or Cu has, on one of or on both the bottom side and the top side, a film of refractory metal such as Ti, Mo, W, Cr, Ta, Nd, Sc, or Y, or a metal nitride film thereof (e.g., a titanium nitride film, a molybdenum nitride film, or a tungsten nitride film) may be used.

Further, the electrically conductive film may have a single-layer structure or a stacked-layer structure of two or more layers. For example, a single-layer structure of an aluminum film containing silicon, a two-layer structure in which a titanium film is tacked over an aluminum film, a three-layer structure in which a titanium film, an aluminum film, and a titanium film are stacked in this order, and the like can be given.

Alternatively, the electrically conductive film may be formed with electrically conductive metal oxide. As the electrically conductive metal oxide, indium oxide, tin oxide, zinc oxide, an alloy of indium oxide and tin oxide, an alloy of indium oxide and zinc oxide, or an electrically conductive metal oxide material containing silicon or silicon oxide can be used.

Note that in the case where heat treatment is performed after the electrically conductive film is formed, the electrically conductive film preferably has heat resistance high enough to withstand the heat treatment.

Subsequently, in a third photolithography step, a resist mask is formed over the electrically conductive film, and selective etching is performed, so that the source electrode layer 515a and the drain electrode layer 515b are formed. Then, the resist mask is removed (see FIG. 2C).

Through the fabrication process, a surface of the electrically conductive film serving as the source electrode layer and the drain electrode layer is stabilized by forming the passive state, for example. Further, the source electrode layer and the drain electrode layer are preferably formed using one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode so that the long-term reliability of the semiconductor device is improved.

Light exposure at the time of the formation of the resist mask in the third photolithography step may be performed using ultraviolet light, KrF laser light, or ArF laser light. A channel length L of a transistor which is subsequently formed is determined by a distance between bottom ends of the source electrode layer and the drain electrode layer, which are adjacent to each other over the oxide semiconductor layer 531. In the case where light exposure is performed for a channel length L less than 25 nm, the light exposure at the time of the formation of the resist mask in the third photolithography step should be performed using extreme ultraviolet light having an extremely short wavelength of several nanometers to several tens of nanometers. In the light exposure by extreme ultraviolet light, the resolution is high and the focus depth is large. Thus, the channel length L of the transistor which is subsequently formed can be longer than or equal to 10 nm and shorter than or equal to 1000 nm and the operation speed of a circuit can be increased.

Note that it is preferable that etching conditions be optimized so as not to etch and divide the oxide semiconductor layer 531 when the electrically conductive film is etched. However, it is difficult to obtain conditions under which only the electrically conductive film is etched and the oxide semiconductor layer 531 is not etched at all. Therefore, in some cases, only part of the oxide semiconductor layer 531 is etched to be an oxide semiconductor layer having a groove (a depressed portion) at the time of etching of the electrically conductive film.

In this embodiment, a Ti film is used as the electrically conductive film and an In—Ga—Zn—O-based oxide semiconductor is used for the oxide semiconductor layer 531; therefore, an ammonia hydrogen peroxide mixture (a mixed solution of ammonia, water, and a hydrogen peroxide solution) is used as an etchant. When the ammonia hydrogen peroxide mixture is used as the etchant, the electrically conductive film can be selectively etched.

### [1-6. Protective Insulating Layer]

Next, by plasma treatment using a gas such as N₂O, N₂, or Ar, water or the like adsorbed on a surface of an exposed portion of the oxide semiconductor layer may be removed. Further, plasma treatment using a mixture gas of oxygen and argon may be performed. In the case where the plasma treatment is performed, the first insulating layer 516 serving as a protective insulating layer which is in contact with part of the oxide semiconductor layer is formed without being exposed to air.

The first insulating layer 516 preferably contains as little impurities such as moisture, hydrogen, and oxygen as possible, and may be an insulating film of a single layer or formed with a stack of insulating films. The first insulating layer 516 can be formed to a thickness of at least 1 nm or more by a method by which impurities such as water and hydrogen are not mixed into the first insulating layer 516, such as a sputtering method, as appropriate. Hydrogen enters the oxide semiconductor layer or extracts oxygen from the oxide semiconductor layer when contained in the first insulating layer 516, which might cause a reduction in resistance of a back channel of the oxide semiconductor layer (i.e., makes an n-type back channel) to a degree that a parasitic channel might be formed. Therefore, it is important that a film formation method in which hydrogen is not used be employed so that the first insulating layer 516 contains as little hydrogen as possible.

The first insulating layer 516 is preferably formed using a material having a high barrier property. For example, a silicon nitride film, a silicon nitride oxide film, an aluminum nitride film, an aluminum nitride oxide film, an aluminum oxide film, a gallium oxide film, or the like can be used as the insulating film having a high barrier property. By use of the insulating film having a high barrier property, impurities such as moisture or hydrogen can be prevented from entering the island-shaped oxide semiconductor layer, the gate insulating layer, or the interface between the island-shaped oxide semiconductor layer and another insulating layer and the vicinity thereof.

For example, an insulating film having a structure in which an aluminum oxide film having a thickness of 100 nm formed by a sputtering method is stacked over a gallium oxide film having a thickness of 200 nm formed by a sputtering method may be formed. The substrate temperature in film formation should be in the range of greater than or equal to room temperature and less than or equal to 300° C. Further, the insulating film preferably contains much oxygen whose amount exceeds that in the stoichiometric proportion, more preferably contains oxygen more than 1 time and less than two times the stoichiometric proportion. When the insulating film thus contains excessive oxygen, oxygen is supplied to the interface with the island-shaped oxide semiconductor film, and oxygen deficiency can be reduced.

In this embodiment, a silicon oxide film having a thickness of 200 nm is formed as the first insulating layer 516 by a sputtering method. The substrate temperature at the film formation should be higher than or equal to room temperature and lower than or equal to 300° C., and is set to 100° C. in this embodiment. The silicon oxide film can be formed by a sputtering method under a rare gas (typically argon) atmosphere, an oxygen atmosphere, or a mixed atmosphere containing a rare gas and oxygen. Further, a silicon oxide target or a silicon target can be used as a target. For example, the silicon oxide film can be formed using a silicon target under an atmosphere containing oxygen by a sputtering method. As the first insulating layer 516 which is formed in contact with the oxide semiconductor layer, an inorganic insulating film that does not contain impurities such as moisture, a hydrogen ion, and OH⁻ and blocks the entry of these impurities from the outside is used. Typically, a silicon oxide film, a silicon oxynitride film, an aluminum oxide film, an aluminum oxynitride film, or the like is used.

As in the case where the oxide semiconductor film 530 is formed, an entrapment vacuum pump (e.g., a cryopump) is preferably used in order to remove moisture remaining in a film formation chamber for the first insulating layer 516. The concentration of impurities in the first insulating layer 516 can be reduced by formation in the film formation chamber exhausted with a cryopump. Further, a turbo pump provided with a cold trap may be used as an exhaustion unit for removing moisture remaining in the film formation chamber for the first insulating layer 516.

A high-purity gas from which impurities such as hydrogen, water, hydroxyl, or hydride is removed is preferably used as a sputtering gas used for the formation of the first insulating layer 516.

Note that second heat treatment may be performed after the first insulating layer 516 is formed. The heat treatment is performed under a nitrogen atmosphere, an atmosphere of ultra-dry air, or a rare gas (e.g., argon and helium) atmosphere at preferably a temperature higher than or equal to 200° C. and lower than or equal to 400° C., for example, higher than or equal to 250° C. and lower than or equal to 350° C. It is desirable that the content of water in the gas be less than or equal to 20 ppm, preferably less than or equal to 1 ppm, or more preferably less than or equal to 10 ppb. For example, the heat treatment is performed at 250° C. for 1 hour under a nitrogen atmosphere. Alternatively, RTA treatment may be performed at a high temperature for a short time as in the first heat treatment. Even when oxygen deficiency is generated in the island-shaped oxide semiconductor layer by the first heat treatment, the heat treatment after the first insulating layer 516 containing oxygen is provided causes oxygen supply to the island-shaped oxide semiconductor layer from the first insulating layer 516. Preferably, the oxygen supply to the island-shaped oxide semiconductor layer can reduce the oxygen deficiency which serves as in the island-shaped oxide semiconductor layer so that the island-shaped oxide semiconductor layer contains oxygen whose amount exceeds that in the stoichiometric proportion. As a result, the island-shaped oxide semiconductor layer can be made to be a substantially i-type and variation in electric characteristics of the transistor due to the oxygen deficiency can be reduced, so that improvement in electric characteristics can be realized. The timing of this second heat treatment is not particularly limited as far as it is after the formation of the first insulating layer 516, and when the second heat treatment serves as another step such as heat treatment in formation of a resin film or heat treatment for reduction of the resistance of an electrically conductive film having a light-transmitting property, the island-shaped oxide semiconductor layer can be made to be a substantially i-type without increasing the number of steps.

Moreover, the oxygen deficiency which serves as in the island-shaped oxide semiconductor layer may be reduced by subjecting the island-shaped oxide semiconductor layer to the heat treatment under an oxygen atmosphere so that oxygen is added to the oxide semiconductor. The heat treatment is performed at a temperature higher than or equal to 100° C. and lower than 350° C., preferably higher than or equal to 150° C. and lower than 250° C., for example. It is preferable that an oxygen gas used for the heat treatment under an oxygen atmosphere do not include water, hydrogen, or the like. Alternatively, it is preferable that the purity of the oxygen gas which is introduced into the heat treatment apparatus be set to be higher than or equal to 6N (99.9999%), more preferably higher than or equal to 7N (99.99999%) (that is, the impurity concentration in the oxygen is lower than or equal to 1 ppm, preferably lower than or equal to 0.1 ppm).

In this embodiment, the second heat treatment (preferably at a temperature higher than or equal to 200° C. and lower than or equal to 400° C., for example, higher than or equal to 250° C. and lower than or equal to 350° C.) is performed under an inert gas atmosphere or an oxygen gas atmosphere. For example, the second heat treatment is performed at 250° C. for 1 hour under a nitrogen atmosphere. In the second heat treatment, part of the oxide semiconductor layer (channel formation region) is heated while being in contact with the first insulating layer 516.

The second heat treatment has the effect that, although oxygen which is one of main components of the oxide semiconductor might be reduced by the above first heat treatment whereas an impurity such as hydrogen, moisture, hydroxyl, or hydride (also referred to as a hydrogen compound) is intentionally removed from the oxide semiconductor layer, the second heat treatment supplies oxygen to the oxide semiconductor layer subjected to the first heat treatment, and accordingly the oxide semiconductor layer is highly purified to be an electrically i-type (intrinsic).

Through the above process, the transistor 510 is formed (see FIG. 2D). The transistor 510, which has a channel-etched structure, includes the gate electrode layer 511, the gate insulating layer 507 over the gate electrode layer 511, the island-shaped oxide semiconductor layer 531 which is over the gate insulating layer 507 and overlaps with the gate electrode layer 511, and a pair of layers, the source electrode layer 515a and the drain electrode layer 515b formed over the island-shaped oxide semiconductor layer 531.

Further, with use of a silicon oxide layer having many defects as the first insulating layer 516, heat treatment after formation of the silicon oxide layer has an effect in diffusing impurities, such as hydrogen, moisture, hydroxyl, or hydride contained in the oxide semiconductor layer, into the oxide insulating layer so that the impurities contained in the oxide semiconductor layer can be further reduced.

In addition, when a silicon oxide layer containing excessive oxygen is used as the first insulating layer 516, oxygen in the first insulating layer 516 is moved to the oxide semiconductor layer 531 by the heat treatment performed after the formation of the first insulating layer 516, so that the oxygen concentration in the oxide semiconductor layer 531 can be improved and higher purification can be achieved.

A second insulating layer 506 serving as a protective insulating layer may be further stacked over the first insulating layer 516. As the second insulating layer 506, for example, a silicon nitride film is formed by an RF sputtering method. Since an RF sputtering method has high productivity, it is preferably used as a film formation method of the protective insulating layer. As the protective insulating layer, an inorganic insulating film which does not contain impurities such as moisture and blocks the entry of the impurities from the outside is used; for example, a silicon nitride film, an aluminum nitride film, or the like is used. Especially a silicon nitride film and an aluminum nitride film are effective as barrier films against hydrogen ions or hydrogen atoms, and either of these is preferably formed over the first insulating layer 516. In this embodiment, the second insulating layer 506 is formed using a silicon nitride film (see FIG. 2E).

In this embodiment, as the second insulating layer 506, a silicon nitride film is formed by heating the substrate 505, over which layers up to the first insulating layer 516 are formed, to a temperature of 100° C. to 400° C., introducing a sputtering gas containing high-purity nitrogen from which hydrogen and moisture are removed, and using a target of silicon semiconductor. Also in this case, the second insulating layer 506 is preferably formed while moisture remaining in a treatment chamber is removed, in the same way as that of the first insulating layer 516.

After the formation of the protective insulating layer, heat treatment may be further performed at a temperature higher than or equal to 100° C. and lower than or equal to 200° C. in the air for longer than or equal to 1 hour and shorter than or equal to 30 hours. This heat treatment may be performed at a fixed heating temperature. Alternatively, the following change in the heating temperature may be performed more than once repeatedly: the heating temperature is increased from room temperature to a temperature higher than or equal to 100° C. and lower than or equal to 200° C. and then decreased to room temperature.

Oxygen-dope treatment may be performed on the oxide semiconductor film 530 and/or the gate insulating layer 507. Note that the “oxygen doping” means that oxygen (which includes at least one of an oxygen radical, an oxygen atom, and an oxygen ion) is added to a bulk. Note that the term “bulk” is used in order to clarify that oxygen is added not only to a surface of a thin film but also to the inside of the thin film. In addition, “oxygen doping” includes “oxygen plasma doping” in which oxygen which is made to be plasma is added to a bulk.

The oxygen plasma-dope treatment may be either a method by which oxygen which is made to be plasma by inductively coupled plasma (ICP) is added or a method by which oxygen which is made to be plasma with the use of a microwave whose frequency is 1 GHz or higher (e.g., a frequency of 2.45 GHz) is added.

### [1-7. Insulating Layer for Planarization]

A planarization layer 517 for planarization can be provided over the first insulating layer 516 (over the second insulating layer 506 in the case where the second insulating layer 506 is stacked). For the planarization layer 517, a resin material such as polyimide, acrylic, benzocyclobutene resin, polyamide, or epoxy can be used. Other than the above resin materials, it is also possible to use a low-dielectric constant material (a low-k material), a siloxane-based resin, PSG (phosphosilicate glass), BPSG (borophosphosilicate glass), or the like. Note that the planarization layer 517 may be formed by stacking a plurality of insulating films formed with any of these materials. There is no particular limitation on the formation method of the planarization layer 517, and any of the following methods can be employed depending on the material: a sputtering method, an SOG method, spin coating, dip coating, spray coating, or a droplet discharging method (e.g., an inkjet method), a printing method (e.g., screen printing or offset printing), or with a tool (equipment) such as a doctor knife, a roll coater, a curtain coater, or a knife coater.

### [Second Step: Formation of First Electrode]

Next, an opening 518 is formed in the first insulating layer 516 (in the second insulating layer 506 in the case where the second insulating layer 506 is formed) and the planarization layer 517. The opening 518 reaches the source electrode layer 515a or the drain electrode layer 515b

An electrically conductive film is formed over the planarization layer 517. As the first electrode 601, the electrically conductive film that can be used for the gate electrode layer 511, the electrically conductive film that can be used for the source electrode layer and the drain electrode layer, an electrically conductive film that transmits visible light, or the like can be used. As the electrically conductive film that transmits visible light, for example, an electrically conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, indium tin oxide to which silicon oxide is added, or graphene can be given, for example.

Through the fabrication process, a surface of the electrically conductive film is stabilized by forming the passive state, for example. Note that the electrically conductive film is preferably formed using one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode so that the long-term reliability of the semiconductor device is improved.

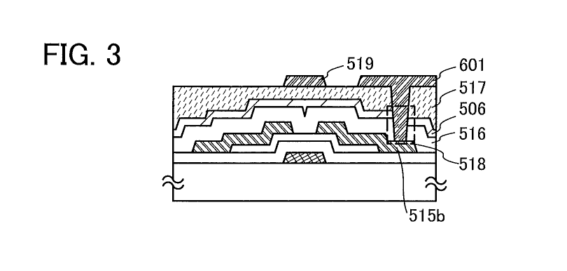

Then, the electrically conductive film is patterned to form the first electrode 601. The first electrode is connected to the source electrode layer 515a or the drain electrode layer 515b through the opening 518 (see FIG. 3).

In addition, a back-gate electrode 519 may be formed in a position overlapping with the channel formation region of the oxide semiconductor layer 531 in the same step as the first electrode 601.

When the back-gate electrode is formed with an electrically conductive film having a light-blocking property, photodegradation of the transistor, such as negative-bias stress photodegradation, can be reduced and the reliability can be increased.

Through the above steps, the enhancement-type transistor that has the channel formation region using the oxide semiconductor, which is provided with the first electrode electrically connected to the source electrode layer or the drain electrode layer, can be manufactured.

This embodiment can be combined with any of the other embodiments in this specification as appropriate.

### Embodiment 3

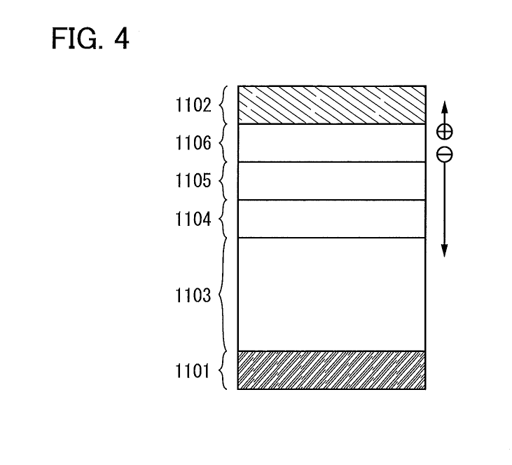

In this embodiment, a structure of a light-emitting element applicable to the semiconductor device described in Embodiment 1 and a method for manufacturing the light-emitting element will be described with reference to FIG. 4. Specifically is described a light-emitting element including a first electrode that is electrically connected to a source and drain electrode layers of a transistor that has a channel formation region using an oxide semiconductor and is one of an anode and a cathode, a second electrode that is the other thereof, and an organic layer containing a light-emitting substance between the first electrode and the second electrode.

FIG. 4 illustrates one example of a structure of a light-emitting element which can be used for a light-emitting device given as an example in this embodiment. In the light-emitting element illustrated in FIG. 4, one of the first and second electrodes is an anode 1101 and the other thereof is a cathode 1102, between which an organic layer 1103 containing a light-emitting substance is interposed. A first charge generation region 1106, an electron-relay layer 1105, and an electron-injection buffer 1104 are sequentially stacked from the cathode 1102 side between the cathode 1102 and the organic layer 1103 containing a light-emitting substance.

In the first charge generation region 1106, holes and electrons are generated, and the holes move into the cathode 1102 and the electrons move into the electron-relay layer 1105. The electron-relay layer 1105 has a high electron-transport property and immediately transfers the electrons generated in the first charge generation region 1106 to the electron-injection buffer 1104. Further, the electron-injection buffer 1104 can reduce a barrier to electron injection into the organic layer 1103 containing a light-emitting substance to enhance the efficiency of the electron injection into the organic layer 1103 containing a light-emitting substance. Thus, electrons generated in the first charge generation region 1106 are injected into the LUMO level of the organic layer 1103 containing a light-emitting substance through the electron-relay layer 1105 and the electron-injection buffer 1104.

Note that the LUMO level of the substance used for the electron-relay layer 1105 is formed so as to be a level between the acceptor level of an acceptor substance in the first charge generation region 1106 and the LUMO level of the organic layer 1103 containing a light-emitting substance. Specifically, it is preferable that the LUMO level of the electron-relay layer 1105 be approximately greater than or equal to −5.0 eV and less than or equal to −3.0 eV. In addition, the electron-relay layer 1105 can prevent interaction in which the substance included in the first charge generation region 1106 and the substance included in the electron-injection buffer 1104 react with each other at the interface therebetween to damage the functions of the first charge generation region 1106 and the electron-injection buffer 1104.

Next, materials that can be used for the above-described light-emitting element are specifically described.

### [Structure of Second Electrode]

The second electrode is formed using an inert, electrically conductive material which hardly causes reduction of an impurity including a hydrogen atom (e.g., moisture) and production of a hydrogen ion or a hydrogen molecule. Examples of the inert, electrically conductive material which hardly produces a hydrogen ion or a hydrogen molecule are a metal having a higher oxidation-reduction potential than the standard hydrogen electrode, an alloy of metals each having a higher oxidation-reduction potential than the standard hydrogen electrode, and an electrically conductive metal oxide having a higher oxidation-reduction potential than the standard hydrogen electrode. Further, the second electrode can be formed using a stack of electrically conductive layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

Examples of the metal having a higher oxidation-reduction potential than the standard hydrogen electrode are antimony (Sb), arsenic (As), bismuth (Bi), copper (Cu), tellurium (Te), mercury (Hg), silver (Ag), palladium (Pd), platinum (Pt), gold (Au), and the like. For the second electrode, such a metal should be used alone or an alloy thereof should be used. The reduction action by such a metal is weak, and an electrically conductive layer that contains the above metal at an amount greater than or equal to 99 at % and less than 100 at % becomes inert and hardly causes reduction of an impurity including a hydrogen atom (e.g., moisture) and production of a hydrogen ion or a hydrogen molecule.

Especially a silver-palladium (Ag—Pd) alloy or a silver-copper (Ag—Cu) alloy has high reflectivity with respect to visible light, and therefore is suitable when the second electrode is used as the reflective electrode.

Examples of the electrically conductive metal oxide having a higher oxidation-reduction potential than the standard hydrogen electrode are indium oxide containing tungsten oxide (IWO), indium zinc oxide containing tungsten oxide (IWZO), indium oxide containing titanium oxide (Ti—InO), indium tin oxide containing titanium oxide (Ti—ITO), indium tin oxide (ITO), indium zinc oxide (IZO), indium tin oxide to which silicon oxide is added (ITSO), tin oxide (SnOx), tungsten oxide, titanium oxide (TiOx), and the like. The reduction action by such an electrically conductive metal oxide having a higher oxidation-reduction potential than the standard hydrogen electrode is weak, and the metal oxide hardly causes reduction of an impurity including a hydrogen atom (e.g., moisture) and production of a hydrogen ion or a hydrogen molecule.

In particular, an electrically conductive metal oxide layer that has a higher oxidation-reduction potential than the standard hydrogen electrode and transmits visible light is preferred in the case where light emission from the organic layer containing a light-emitting substance is extracted to the second electrode.

A stack of layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode can also be used to form the second electrode. For example, the electrically conductive metal oxide layer that has a higher oxidation-reduction potential than the standard hydrogen electrode and transmits visible light is formed between a metal layer that has high reflectivity and a higher oxidation-reduction potential than the standard hydrogen electrode and the organic layer containing a light-emitting substance, so that the distance between the organic layer containing a light-emitting substance and a reflective electrode can be adjusted. By adjustment of the distance between them, the light extraction efficiency and emission spectrum of the light-emitting element can be changed.

In the case where the second electrode is used as the cathode 1102, owing to the first charge generation region 1106 provided in contact with the cathode 1102, a variety of electrically conductive materials can be used for the cathode 1102 regardless of their work functions. Specifically, besides a material that has a low work function, a material that has a high work function can also be used.

Further, in the case where the second electrode is used as the anode 1101, providing a second charge generation region in contact with the anode 1101 enables use of a variety of conductive materials for the anode 1101 regardless of their work functions. Specifically, besides a material that has a high work function, a material that has a low work function can also be used. A material for forming the second charge generation region will be described later together with a material for forming the first charge generation region.

Note that any of a variety of methods can be selected as a method of forming the second electrode depending on a material used for the second electrode. For example, a vacuum evaporation method (e.g., an EB method or a resistance heating method), a sputtering method, or the like can be used. A wet process, such as an inkjet method or a spin coating method, may be used without limitation to a dry process.

Note that the reliability is impaired by entry of impurity such as water and/or oxygen into the organic layer containing a light-emitting substance. Therefore, in the case where the second electrode is formed in contact with the organic layer containing a light-emitting substance, precaution should be taken to prevent the entry of an impurity such as water and/or oxygen, so that the second electrode is also kept clean. For example, through evaporation for the second electrode in a pressure of about 10×10⁻⁵ Pa, the second electrode is difficult to oxidize and is formed while a surface thereof is kept active. Thus, if the second electrode contains an active, electrically conductive material that reduces an impurity including a hydrogen atom (e.g., moisture), a hydrogen ion or a hydrogen molecule is produced and diffused into the semiconductor device.

### [Structure of First Electrode]

In the case where the first electrode is used as the anode, the anode 1101 is preferably formed using a metal, an alloy, an electrically conductive compound, a mixture of these materials, or the like which has a high work function (specifically, a work function higher than or equal to 4.0 eV is more preferable). Specifically, for example, indium tin oxide (ITO), indium tin oxide containing silicon or silicon oxide, indium zinc oxide (IZO), and indium oxide containing tungsten oxide and zinc oxide can be given.

Films of these conductive metal oxide films are usually formed by a sputtering method; however, a sol-gel method or the like may also be used. For example, a film of indium zinc oxide (IZO) can be formed by a sputtering method using a target in which zinc oxide is added to indium oxide at 1 wt % to 20 wt %. A film of indium oxide containing tungsten oxide and zinc oxide can be formed by a sputtering method using a target in which tungsten oxide and zinc oxide are added to indium oxide at 0.5 wt % to 5 wt % and 0.1 wt % to 1 wt %, respectively.

Besides, for example, the following can be given: gold (Au), platinum (Pt), nickel (Ni), tungsten (W), chromium (Cr), molybdenum (Mo), iron (Fe), cobalt (Co), copper (Cu), palladium (Pd), titanium (Ti), nitride of a metal material (e.g., titanium nitride), molybdenum oxide, vanadium oxide, ruthenium oxide, tungsten oxide, manganese oxide, titanium oxide, and the like. Alternatively, an electrically conductive polymer such as poly(3,4-ethylenedioxythiophene)/poly(styrenesulfonic acid) (PEDOT/PSS) or polyaniline/poly(styrenesulfonic acid) (PAni/PSS) may be used.

Note that in the case where the second charge generation region is provided in contact with the anode 1101, a variety of electrically conductive materials can be used for the anode 1101 regardless of their work functions. Specifically, besides a material having a high work function, a material having a low work function can also be used. A material for forming the second charge generation region will be subsequently described together with a material for forming the first charge generation region.

In the case where the first electrode is used as the cathode, owing to the first charge generation region 1106 provided in contact with the cathode 1102 between the cathode 1102 and the organic layer 1103 containing a light-emitting substance, a variety of electrically conductive materials can be used for the cathode 1102 regardless of their work functions.

Note that at least one of the cathode 1102 and the anode 1101 may be formed using an electrically conductive film that transmits visible light. For the electrically conductive film that transmits visible light, for example, indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, and indium tin oxide to which silicon oxide is added can be given.

Further, a metal thin film having a thickness enough to transmit light (preferably, approximately 5 nm to 30 nm) can also be used as the electrically conductive film that transmits visible light.

[Structure of Organic Layer containing Light-Emitting Substance]

The organic layer 1103 containing a light-emitting substance includes at least a light-emitting layer, and may have a stacked-layer structure in which a layer/layers other than the light-emitting layer is/are stacked on the light-emitting layer. As the layers other than the light-emitting layer, for example, there are layers formed of a material having a high hole-injection property, a material having a high hole-transport property, a material having a high electron-transport property, a material having a high electron-injection property, a material having a bipolar property (a material having high electron-and-hole-transport properties), and the like. Specifically, a hole-injection layer, a hole-transport layer, a light-emitting layer, a hole-blocking layer, an electron-transport layer, an electron-injection layer, and the like are given, and they can be combined as appropriate and stacked from the anode side.

Specific examples of the materials for the layers included in the above organic layer 1103 containing a light-emitting substance are described below.

The hole-injection layer is a layer containing a substance having a high hole-injection property. As the substance having a high hole-injection property, for example, molybdenum oxide, vanadium oxide, ruthenium oxide, tungsten oxide, manganese oxide, or the like can be used. Besides, it is possible to use a phthalocyanine-based compound such as phthalocyanine (abbreviation: H₂Pc) or copper phthalocyanine (abbreviation: CuPc), a high molecule such as poly(3,4-ethylenedioxythiophene)/poly(styrenesulfonic acid) (PEDOT/PSS), or the like to form the hole-injection layer.

Note that the hole-injection layer may be formed using the second charge generation region. When the second charge generation region is used for the hole-injection layer, a variety of electrically conductive materials can be used for the anode 1101 regardless of their work functions as described above. A material for forming the second charge generation region will be subsequently described together with a material for forming the first charge generation region.

The hole-transport layer is a layer containing a substance having a high hole-transport property. As the substance having a high hole-transport property, the following can be given, for example: aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4-phenyl-4′-(9-phenylfluoren-9-yl)triphenylamine (abbreviation: BPAFLP), 4,4′,4″-tris(carbazol-9-yl)triphenylamine (abbreviation: TCTA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB); 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like. Any of the following carbazole derivatives can be used: 4,4′-di(N-carbazolyl)biphenyl (abbreviation: CBP); 1,3,5-tris[4-(N-carbazolyl)phenyl]benzene (abbreviation: TCPB); and 9-[4-(10-phenyl-9-anthracenyl)phenyl]-9H-carbazole (abbreviation: CzPA). The substances mentioned here are mainly ones that have a hole mobility more than or equal to 10⁻⁶ cm²/Vs. However, any substance other than the above substances may also be used as far as it is a substance in which the hole-transport property is higher than the electron-transport property. The layer containing a substance having a high hole-transport property is not limited to a single layer, and two or more layers containing the aforementioned substances may be stacked.

In addition to the above substances, a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used for the hole-transport layer.

The light-emitting layer is the layer containing a light-emitting substance. As the light-emitting substance, any of the following fluorescent compounds can be used. Examples thereof are N,N′-bis[4-(9H-carbazol-9-yl)phenyl]-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM²), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), SD1 (product name, manufactured by SFC Co., Ltd), and the like.

As the light-emitting substance, any of the following phosphorescent compounds can also be used. Examples thereof are bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III)picolinate (abbreviation: FIrpic), bis[2-(3′,5′-bistrifluoromethylphenyl)pyridinato-N,C^{2′}]iridium(III)picolinate (abbreviation: Ir(CF₃ ppy)₂(pic)), bis[2-(4′,6′-difluorophenyl)pyridinato-N,C^{2′}]iridium(III) acetylacetonate (abbreviation: FIracac), tris(2-phenylpyridinato)iridium(III) (abbreviation: Ir(ppy)₃), bis(2-phenylpyridinato)iridium(III)acetylacetonato (abbreviation: Ir(ppy)₂(acac)), bis(benzo[h]quinolinato)iridium(III)acetylacetonate (abbreviation: Ir(bzq)₂(acac)), bis(2,4-diphenyl-1,3-oxazolato-N,C^{2′})iridium(III)acetylacetonate (abbreviation: Ir(dpo)₂(acac)), bis[2-(4′-perfluorophenylphenyl)pyridinato]iridium(III)acetylacetonate (abbreviation: Ir(p-PF-ph)₂(acac)), bis(2-phenylbenzothiazolato-N,C^{2′})iridium(III)acetylacetonate (abbreviation: Ir(bt)₂(acac)), bis[2-(2′-benzo[4,5-α]thienyl)pyridinato-N,C^{3′}]iridium(III) acetylacetonate (abbreviation: Ir(btp)₂(acac)), bis(1-phenylisoquinolinato-N,C^{2′})iridium(III)acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), (acetylacetonato)bis(2,3,5-triphenylpyrazinato)iridium(III) (abbreviation: Ir(tppr)₂(acac)), 2,3,7,8,12,13,17,18-octaethyl-21H,23H-porphyrin platinum(II) (abbreviation: PtOEP), tris(acetylacetonato)(monophenanthroline)terbium(III) (abbreviation: Tb(acac)₃(Phen)), tris(1,3-diphenyl-1,3-propanedionato)(monophenanthroline)europium(III) (abbreviation: Eu(DBM)₃(Phen)), tris[1-(2-thenoyl)-3,3,3-trifluoroacetonato](monophenanthroline)europium(III) (abbreviation: Eu(TTA)₃(Phen)), and (dipivaloylmethanato)bis(2,3,5-triphenylpyrazinato)iridium(III) (abbreviation: Ir(tppr)₂(dpm)), and the like.

Note that those light-emitting substances are preferably dispersed in a host material. As the host material, for example, the following can be used: an aromatic amine compound such as NPB, TPD, TCTA, TDATA, MTDATA, or BSPB; a carbazole derivative such as PCzPCA1, PCzPCA2, PCzPCN1, CBP, TCPB, CzPA, 9-phenyl-3-[4-(10-phenyl-9-anthryl)phenyl]-9H-carbazole (abbreviation: PCzPA), or 4-phenyl-4′-(9-phenyl-9H-carbazol-3-yl)triphenylamine (abbreviation: PCBA1BP); a substance having a high hole-transport property which contains a high molecular compound, such as PVK, PVTPA, PTPDMA, or Poly-TPD; a metal complex having a quinoline skeleton or a benzoquinoline skeleton, such as tris(8-quinolinolato)aluminum (abbreviation: Alq), tris(4-methyl-8-quinolinolato)aluminum (abbreviation: Almq₃), bis(10-hydroxybenzo[h]-quinolinato)beryllium (abbreviation: BeBq₂), or bis(2-methyl-8-quinolinolato)(4-phenylphenolato)aluminum (abbreviation: BAlq); a metal complex having an oxazole-based or thiazole-based ligand, such as bis[2-(2-hydroxyphenyl)benzoxazolato]zinc (abbreviation: Zn(BOX)₂) or bis[2-(2-hydroxyphenyl)-benzothiazolato]zinc (abbreviation: Zn(BTZ)₂); or a substance having a high electron-transport property, such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]carbazole (abbreviation: CO11), 3-(4-biphenylyl)-4-phenyl-5-(4-tert-butylphenyl)-1,2,4-triazole (abbreviation: TAZ), bathophenanthroline (abbreviation: BPhen), or bathocuproine (abbreviation: BCP).

The electron-transport layer is a layer containing a substance having a high electron-transport property. As the substance having a high electron-transport property, for example, a metal complex having a quinoline skeleton or a benzoquinoline skeleton, such as Alq, Almq₃, BeBq₂, or BAlq can be used. In addition to the above, a metal complex having an oxazole-based or thiazole-based ligand, such as Zn(BOX)₂ or Zn(BTZ)₂ can also be used, for example. Further, besides the metal complex, PBD, OXD-7, CO11, TAZ, BPhen, BCP, 2-[4-(dibenzothiophen-4-yl)phenyl]-1-phenyl-1H-benzimidazole (abbreviation: DBTBIm-II), or the like can also be used. The substances mentioned here are mainly ones that have an electron mobility more than or equal to 10⁻⁶ cm²/Vs. Note that any substance other than the above substances may also be used as far as it is a substance in which the electron-transport property is higher than the hole-transport property. Furthermore, the electron-transport layer may have a structure in which two or more layers formed of the above substances are stacked, without limitation to a single-layer structure.

Alternatively, a high molecular compound can be used. For example, poly[(9,9-dihexylfluorene-2,7-diyl)-co-(pyridine-3,5-diyl)] (abbreviation: PF-Py) or poly[(9,9-dioctylfluorene-2,7-diyl)-co-(2,2′-bipyridine-6,6′-diyl)] (abbreviation: PF-BPy) can be used.

The electron-injection layer is a layer containing a substance having a high electron-injection property. As the substance having a high electron-injection property, the following can be given: an alkali metal or an alkaline earth metal such as lithium (Li), cesium (Cs), calcium (Ca), lithium fluoride (LiF), cesium fluoride (CsF), and calcium fluoride (CaF₂), and a compound thereof. Alternatively, a layer containing a substance having an electron-transport property and an alkali metal, an alkaline earth metal, or a compound thereof (e.g., Alq containing magnesium (Mg)) can be used. Such a structure increases the efficiency in electron injection from the cathode 1102.

With the stack of these layers in an appropriate combination, the organic layer 1103 containing a light-emitting substance can be formed. Further, as a formation method of the organic layer 1103 containing a light-emitting substance, any of a variety of methods (e.g., a dry process and a wet process) can be selected as appropriate depending on a material to be used. For example, a vacuum evaporation method, an inkjet method, a spin coating method, or the like can be used. Note that a different formation method may be employed for each layer.

Further, between the cathode 1102 and the organic layer 1103 containing a light-emitting substance, the electron-injection buffer 1104, the electron-relay layer 1105, and the first charge generation region 1106 are provided. The first charge generation region 1106 is formed in contact with the cathode 1102, the electron-relay layer 1105 is formed in contact with the first charge generation region 1106, and the electron-injection buffer 1104 is formed in contact with and between the electron-relay layer 1105 and the organic layer 1103 containing a light-emitting substance.

### [Structure of Charge Generation Region]

The first charge generation region 1106 and the second charge generation region are regions containing a substance having a high hole-transport property and an acceptor substance. The charge generation regions may not only include a substance having a high hole-transport property and an acceptor substance in the same film but also includes a stacked layer of a layer containing a substance having a high hole-transport property and a layer containing an acceptor substance. Note that when the first charge generation region has a stacked-layer structure on the cathode side, the layer containing the substance having a high hole-transport property is in contact with the cathode 1102, and when the second charge generation region has a stacked-layer structure provided on the anode side, the layer containing the acceptor substance is in contact with the anode 1101.

Note that the acceptor substance is preferably added to the charge generation region so that the mass ratio of the acceptor substance to the substance having a high hole-transport property is greater than or equal to 0.1:1 and less than or equal to 4.0:1.

As the acceptor substance that is used for the charge generation region, a transition metal oxide and an oxide of a metal belonging to Groups 4 to 8 of the periodic table can be given. Specifically, molybdenum oxide is particularly preferable. Note that molybdenum oxide has a low hygroscopic property.

As the substance having a high hole-transport property used for the charge generation region, any of a variety of organic compounds such as an aromatic amine compound, a carbazole derivative, an aromatic hydrocarbon, and a high molecular compound (e.g., an oligomer, a dendrimer, or a polymer) can be used. Specifically, a substance having a hole mobility more than or equal to 10⁻⁶ cm²/Vs is preferably used. However, any substance other than the above substances may also be used as far as it is a substance in which the hole-transport property is higher than the electron-transport property.

### [Structure of Electron-Relay Layer]

The electron-relay layer 1105 is a layer that can immediately receive electrons drawn out by the acceptor substance in the first charge generation region 1106. Therefore, the electron-relay layer 1105 is a layer containing a substance having a high electron-transport property and is formed to have a LUMO level between the acceptor level of the acceptor in the first charge generation region 1106 and the LUMO level of the organic layer 1103 containing a light-emitting substance. Specifically, it is preferable that the LUMO level of the electron-relay layer 1105 be approximately greater than or equal to −5.0 eV and less than or equal to −3.0 eV. As the substance used for the electron-relay layer 1105, for example, a perylene derivative and a nitrogen-containing condensed aromatic compound can be given. Note that a nitrogen-containing condensed aromatic compound is preferably used for the electron-relay layer 1105 because of its stability. Among nitrogen-containing condensed aromatic compounds, a compound having an electron-withdrawing group, such as a cyano group or a fluoro group, is preferably used because such a compound further facilitates reception of electrons in the electron-relay layer 1105.

Specific examples of the perylene derivative are 3,4,9,10-perylenetetracarboxylic dianhydride (abbreviation: PTCDA), 3,4,9,10-perylenetetracarboxylic bisbenzimidazole (abbreviation: PTCBI), N,N′-dioctyl-3,4,9,10-perylenetetracarboxylic diimide (abbreviation: PTCDI-C8H), N,N′-dihexyl-3,4,9,10-perylenetetracarboxylic diimide (abbreviation: Hex PTC), and the like.

Specific examples of the nitrogen-containing condensed aromatic compound are pirazino[2,3-f][1,10]phenanthroline-2,3-dicarbonitrile (abbreviation: PPDN), 2,3,6,7,10,11-hexacyano-1,4,5,8,9,12-hexaazatriphenylene (abbreviation: HAT(CN)₆), 2,3-diphenylpyrido[2,3-b]pyrazine (abbreviation: 2PYPR), 2,3-bis(4-fluorophenyl)pyrido[2,3-b]pyrazine (abbreviation: F2PYPR), and the like.

Besides, 7,7,8,8-tetracyanoquinodimethane (abbreviation: TCNQ), 1,4,5,8-naphthalenetetracarboxylicdianhydride (abbreviation: NTCDA), perfluoropentacene, copper hexadecafluoro phthalocyanine (abbreviation: F₁₆CuPc), N,N-bis(2,2,3,3,4,4,5,5,6,6,7,7,8,8,8-pentadecafluorooctyl-1,4,5,8-naphthalenetetracarboxylic diimide (abbreviation: NTCDI-C8F), 3′,4′-dibutyl-5,5″-bis(dicyanomethylene)-5,5″-dihydro-2,2′:5′,2″-terthiophen (abbreviation: DCMT), methanofullerene such as [6,6]-phenyl C₆₁ butyric acid methyl ester, or the like can be used for the electron-relay layer 1105.

### [Structure of Electron-Injection Buffer]

The electron-injection buffer 1104 is a layer which facilitates injection of electrons from the first charge generation region 1106 to the organic layer 1103 containing a light-emitting substance. The provision of the electron-injection buffer 1104 between the first charge generation region 1106 and the organic layer 1103 containing a light-emitting substance makes it possible to reduce the injection barrier therebetween.

A substance having a high electron-injection property can be used for the electron-injection buffer 1104: for example, an alkali metal, an alkaline earth metal, a rare earth metal, a compound of the above metal (e.g., an alkali metal compound (including an oxide such as lithium oxide, a halide, or carbonate such as lithium carbonate or cesium carbonate), an alkaline earth metal compound (including an oxide, a halide, or carbonate), or a rare earth metal compound (including an oxide, a halide, or carbonate)).

Further, in the case where the electron-injection buffer 1104 contains a substance having a high electron-transport property and a donor substance, the donor substance is preferably added to the substance having a high electron-transport property so that the mass ratio of the donor substance to the substance having a high electron-transport property is greater than or equal to 0.001:1 and less than or equal to 0.1:1. Note that as the donor substance, an organic compound such as tetrathianaphthacene (abbreviation: TTN), nickelocene, or decamethylnickelocene can be used as well as an alkali metal, an alkaline earth metal, a rare earth metal, a compound of the above metal (e.g., an alkali metal compound (including an oxide of lithium oxide, a halide, or carbonate such as lithium carbonate or cesium carbonate), an alkaline earth metal compound (including an oxide, a halide, or carbonate), or a rare earth metal compound (including an oxide, a halide, or carbonate)). Note that as the substance having a high electron-transport property, a material similar to the above-described material for the electron-transport layer which can be formed in part of the organic layer 1103 containing a light-emitting substance can be used.

Note that in the case where the electron-injection buffer 1104, the electron-injection layer, and the like are used, alkali metal and/or alkaline earth metal is/are added to the organic layer containing a light-emitting substance. If an excessive amount of alkali metal, alkaline earth metal, or a compound thereof is present in the organic layer containing a light-emitting substance, an impurity including a hydrogen atom (e.g., moisture) might be reduced to produce a hydrogen ion or a hydrogen molecule. However, as far as the alkali metal and/or alkaline earth metal is/are used with a metal having a higher oxidation-reduction potential than the standard hydrogen electrode, an alloy having a higher oxidation-reduction potential than the standard hydrogen electrode, an electrically conductive metal oxide having a higher oxidation-reduction potential than the standard hydrogen electrode, or an organic substance and is/are contained at an amount greater than or equal to 4.1×10¹⁴ atoms/cm² and less than or equal to 4.5×10¹⁵ atoms/cm² per unit emission area of the light-emitting element, driving voltage of the semiconductor element and power consumption of the semiconductor device can be reduced without impairment of characteristics of the semiconductor element using the oxide semiconductor and reliability of the semiconductor device using the semiconductor element.

The light-emitting element in which the organic layer containing a light-emitting substance is provided between the first electrode and the second electrode contains alkali metal and/or alkaline earth metal at an amount greater than or equal to 4.1×10¹⁴ atoms/cm² and less than or equal to 4.5×10¹⁵ atoms/cm² per unit emission area. Because of this range, the alkali metal and/or alkaline earth metal functions as a donor substance, and the alkali metal or alkaline earth metal is stabilized in the organic layer containing a light-emitting substance; consequently, reduction of an impurity including a hydrogen atom (e.g., moisture) and production of a hydrogen ion or a hydrogen molecule are not caused.

Further, the light-emitting element described in this embodiment can be fabricated by any of a variety of methods regardless of whether it is a dry process (e.g., a vacuum evaporation method) or a wet process (e.g., an inkjet method or a spin coating method).

The light-emitting element described in this embodiment can be fabricated by combination of the above-described materials. Light emission from the above-described light-emitting substance can be obtained with this light-emitting element, and the emission color can be selected by changing the type of the light-emitting substance. Further, a plurality of light-emitting substances which emit light of different colors can be used, whereby, for example, white light emission can also be obtained by expanding the width of the emission spectrum. Note that in order to obtain white light emission, light-emitting substances which emit light whose colors are complementary may be used, for example, different layers which emit light whose colors are complementary or the like can be used. Specific examples of complementary colors are a combination of blue and yellow, a combination of blue-green and red, and the like.

In the semiconductor element given as an example in this embodiment, an inert, electrically conductive material is used for the second electrode. Consequently, it is possible to suppress a phenomenon in which moisture that remains in the semiconductor device and/or enters the device from the outside thereof reacts with an electrically conductive material to produce a hydrogen ion or a hydrogen molecule.

Production of a hydrogen ion or a hydrogen molecule which increases the carrier concentration in the oxide semiconductor is suppressed, and accordingly, a semiconductor device having excellent reliability can be provided using the oxide semiconductor. Alternatively, a light-emitting device having excellent reliability can be provided using the oxide semiconductor.

This embodiment can be combined with any of the other embodiments in this specification as appropriate.

### Embodiment 4

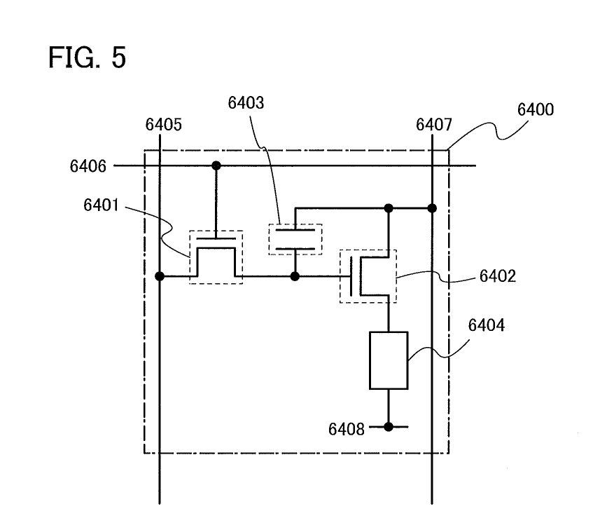

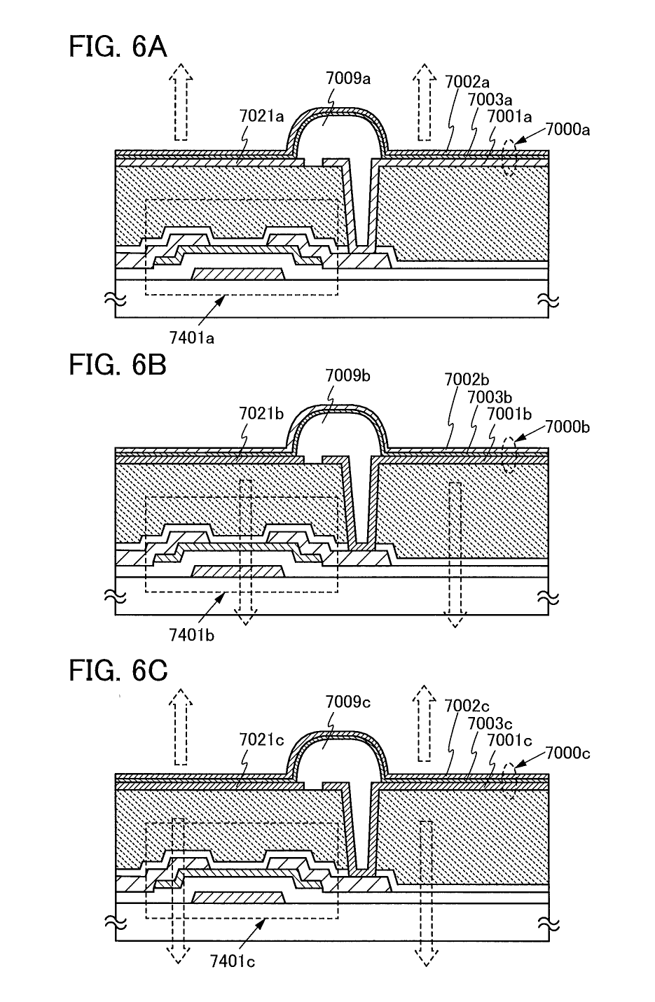

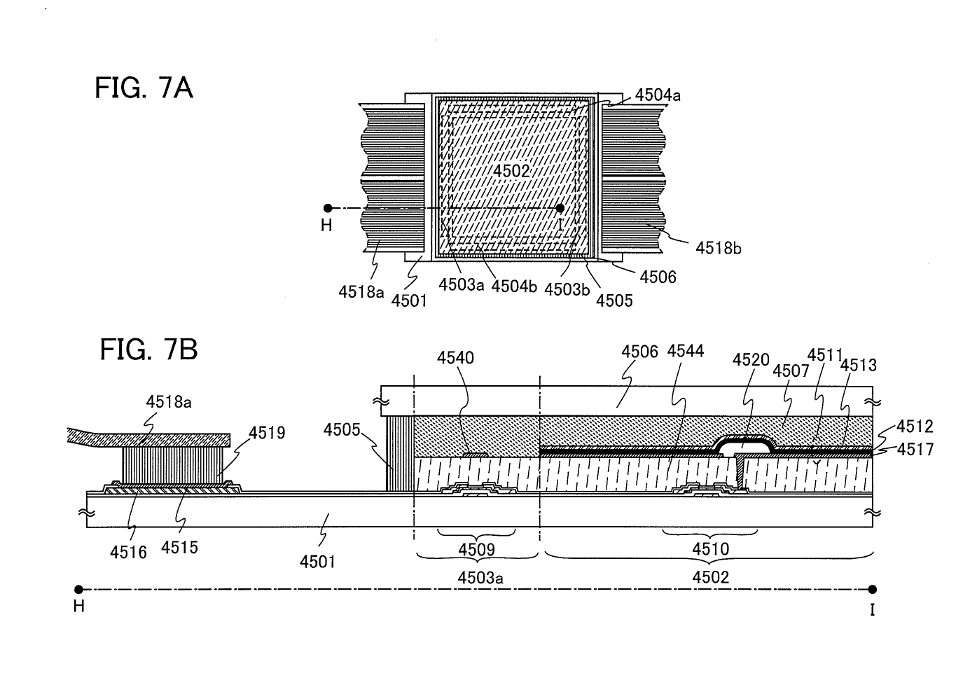

In this embodiment, a light-emitting display device including a plurality of semiconductor devices described in Embodiment 1 will be described with reference to FIG. 5, FIGS. 6A to 6C, and FIGS. 7A and 7B.

### [Configuration of Pixel Circuit]

FIG. 5 is an equivalent circuit diagram illustrating a pixel included in a light-emitting display device which will be given as an example in this embodiment. Note that for the pixel circuit, either digital time gray scale driving or analog gray scale driving can be applied.

A pixel 6400 given as an example in this embodiment includes two n-channel transistors each of which includes an oxide semiconductor layer in a channel formation region. The pixel 6400 includes a switching transistor 6401, a transistor 6402 for driving a light-emitting element, a light-emitting element 6404, and a capacitor 6403. In the switching transistor 6401, a gate is connected to a scan line 6406, a first electrode (one of a source and drain electrode layers) is connected to a signal line 6405, and a second electrode (the other of the source and drain electrode layers) is connected to a gate of the transistor 6402 for driving the light-emitting element. In the transistor 6402 for driving the light-emitting element, the gate is connected to a power supply line 6407 through the capacitor 6403, a first electrode is connected to the power supply line 6407, and a second electrode is connected to a first electrode (a pixel electrode) of the light-emitting element 6404. A second electrode of the light-emitting element 6404 corresponds to a common electrode 6408. The common electrode 6408 is electrically connected to a common potential line provided over the same substrate.

A high power supply potential is supplied to the first electrode (pixel electrode) of the light-emitting element 6404 through the power supply line 6407, and a low power supply potential is supplied to the second electrode (common electrode 6408). The low power supply potential is a potential lower than the high power supply potential, and GND, 0 V, or the like is set as the low power source potential. The high power source potential is set such that a potential difference between the high power supply potential and the low power supply potential equals or exceeds the emission start voltage of the light-emitting element 6404. The potential difference between the two electrodes of the light-emitting element 6404 causes the flow of current, so that light is emitted.

Note that a high power source potential and a low power source potential may be set for the common electrode 6408 and the power supply line 6407, respectively. In that case, the structure of the light-emitting element 6404 may be modified as appropriate because the current in the light-emitting element 6404 flows reversely

Note that the capacitor 6403 can be omitted when replaced with the gate capacitance of the transistor 6402 for driving the light-emitting element. The gate capacitance of the transistor 6402 for driving the light-emitting element may be formed between a channel region and a gate electrode. Further, the capacitor 6403 can be omitted by use of a transistor whose off-state current is reduced as the switching transistor 6401. As the transistor whose off-state current is reduced, a transistor using an oxide semiconductor layer in a channel formation region can be given as an example.

The case where the pixel illustrated in the equivalent circuit diagram of FIG. 5 is driven by digital time gray scale driving will be described. In the case where a voltage-input voltage driving method is employed, a video signal is input to the gate of the transistor 6402 for driving the light-emitting element so that the transistor 6402 for driving the light-emitting element is in either of two states of being sufficiently turned on and turned off. That is, the transistor 6402 for driving the light-emitting element is made to operate in a linear region. Since the transistor 6402 for driving the light-emitting element is made to operate in a linear region, a voltage higher than the voltage of the power supply line 6407 is applied to the gate of the transistor 6402 for driving the light-emitting element. Note that a voltage higher than or equal to the sum of the power supply line voltage and Vₜₕ of the transistor 6402 for driving the light-emitting element is applied to the signal line 6405.

Further, the pixel represented by the equivalent circuit in FIG. 5 can be driven by an analog gray scale method which differs in signal from a digital time gray scale method.

The case where the pixel represented by the equivalent circuit in FIG. 5 is driven by an analog gray scale method will be described. The potential of the power supply line 6407 is made higher than a gate potential of the transistor 6402 for driving the light-emitting element, so that the transistor 6402 for driving the light-emitting element operates in a saturation region. Next, to the gate of the transistor 6402 for driving the light-emitting element, a voltage higher than or equal to the sum of the threshold voltage Vₜₕ of the transistor 6402 for driving the light-emitting element and the voltage at which the light-emitting element 6404 emits light with a desired luminance (also referred to as forward voltage) is applied.

A video signal that includes analog grayscale data and enables the transistor 6402 for driving the light-emitting element to operate in a saturation region is input, so that a current based on the video signal flows through the light-emitting element 6404. In this way, the pixel represented by the equivalent circuit in FIG. 5 can be driven by an analog gray scale method.

Note that the pixel configuration is not limited to that illustrated in FIG. 5. For example, a switch, a resistor, a capacitor, a transistor, a logic circuit, or the like may be added to the pixel illustrated in FIG. 5. Further, a structure may be employed in which a transistor for current control is connected between the transistor for driving the light-emitting element and the light-emitting element.

### [Structure of Pixel]

FIGS. 6A to 6C are each a cross-sectional view of the pixel included in the light-emitting display device given as an example in this embodiment.

At least one of the first and second electrodes of the light-emitting element provided in the pixel transmits visible light, and light emission is extracted to the outside of light-emitting element through the electrode that transmits visible light. Examples of the structures of the light-emitting element are a top emission structure in which light emission is extracted to the side where the light-emitting element is formed without passing through a substrate over which the light-emitting element is formed (FIG. 6A), a bottom emission structure in which light emission is extracted to the side where the light-emitting element is not formed through the substrate over which the light-emitting element is formed (FIG. 6B), and a dual emission structure in which light emission is extracted to both the substrate side on which the light-emitting element is formed and the other side of the substrate through the substrate (FIG. 6C). A light-emitting element having any of these emission structures can be used in combination with the above pixel circuit.

The second electrode of the light-emitting element provided in the pixel is formed using an inert, electrically conductive material which hardly causes reduction of an impurity including a hydrogen atom (e.g., moisture) and production of a hydrogen ion or a hydrogen molecule. Examples of the inert, electrically conductive material which hardly produces a hydrogen ion or a hydrogen molecule are a metal having a higher oxidation-reduction potential than the standard hydrogen electrode, an alloy of metals each having a higher oxidation-reduction potential than the standard hydrogen electrode, and an electrically conductive metal oxide having a higher oxidation-reduction potential than the standard hydrogen electrode. Further, the second electrode may be formed of a stack of electrically conductive layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

Examples of the metal having a higher oxidation-reduction potential than the standard hydrogen electrode are antimony (Sb), arsenic (As), bismuth (Bi), copper (Cu), tellurium (Te), mercury (Hg), silver (Ag), palladium (Pd), platinum (Pt), gold (Au), and the like. For the second electrode, such a metal should be used alone or an alloy thereof should be used. The reduction action by such a metal is weak, and an electrically conductive layer that contains the above metal at an amount greater than or equal to 99 at % and less than 100 at % becomes inert and hardly causes reduction of an impurity including a hydrogen atom (e.g., moisture) and production of a hydrogen ion or a hydrogen molecule.

A metal layer having a sufficient thickness can reflect visible light and therefore can be used as the reflective electrode. Especially a silver-palladium (Ag—Pd) alloy or a silver-copper (Ag—Cu) alloy has high reflectivity with respect to visible light, and is suitable for the reflective electrode accordingly.

Further, the above metal can also be used as an electrically conductive film that transmits visible light by being formed into a film that is sufficiently thin to transmit light (preferably about 5 nm to 30 nm).

Examples of the electrically conductive metal oxide having a higher oxidation-reduction potential than the standard hydrogen electrode are indium oxide containing tungsten oxide (IWO), indium zinc oxide containing tungsten oxide (IWZO), indium oxide containing titanium oxide (Ti—InO), indium tin oxide containing titanium oxide (Ti—ITO), indium tin oxide (ITO), indium zinc oxide (IZO), indium tin oxide to which silicon oxide is added (ITSO), tin oxide (SnOx), tungsten oxide, titanium oxide (TiOx), and the like. The reduction action by such an electrically conductive metal oxide having a higher oxidation-reduction potential than the standard hydrogen electrode is weak, and the metal oxide hardly causes reduction of an impurity including a hydrogen atom (e.g., moisture) and production of a hydrogen ion or a hydrogen molecule.

When an electrically conductive metal oxide layer that has a higher oxidation-reduction potential than the standard hydrogen electrode and transmits visible light is used especially for the second electrode, light emission from the organic layer containing a light-emitting substance can be extracted to the second electrode.

A stack of layers selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode can also be used to form the second electrode.

### (Top Emission Structure)

A light-emitting element having a top emission structure is described with reference to FIG. 6A. The light-emitting element having a top emission structure emits light in a direction indicated by arrows in FIG. 6A.

A pixel, the cross-sectional view of which is given as an example in FIG. 6A, includes a transistor 7401a for driving a light-emitting element and a light-emitting element 7000a. The light-emitting element 7000a includes an organic layer 7003a containing a light-emitting substance provided between a first electrode 7001a and a second electrode 7002a which transmits visible light, and the first electrode 7001a is electrically connected to a source electrode layer or a drain electrode layer of the transistor 7401a.

For the first electrode 7001a, a material that efficiently reflects light emitted from the organic layer 7003a containing a light-emitting substance is preferably used, in which case the light extraction efficiency can be improved. Further, the first electrode 7001a may have a stacked-layer structure. For example, an electrically conductive film that transmits visible light, which is formed on the side that is in contact with the organic layer 7003a containing a light-emitting substance, may be stacked over a light shielding film. As the light shielding film, although a metal film or the like which efficiently reflects light emitted from the organic layer containing a light-emitting substance is preferable, for example, a resin or the like to which a black pigment is added can also be used.

The second electrode 7002a is formed using an electrically conductive film which transmits visible light. For the electrically conductive film which transmits visible light, for example, indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, and indium tin oxide to which silicon oxide is added can be given. Further, a metal thin film having a thickness enough to transmit light (preferably, approximately 5 nm to 30 nm) can also be used. For example, a silver-magnesium (Ag—Mg) alloy film having a thickness of 5 nm can be used as the second electrode 7002a.

Note that one of the first electrode 7001a and the second electrode 7002a functions as an anode, and the other functions as a cathode. It is preferable to use a substance having a high work function for the electrode which functions as an anode, and a substance having a low work function for the electrode which functions as a cathode. Note that in the case where a charge generation layer is provided in contact with the anode, a variety of electrically conductive materials can be used for the anode regardless of their work functions. Specifically, besides a material which has a high work function, a material which has a low work function can also be used. Further, a material having high electrical conductivity is preferably used for each of the first electrode 7001a and the second electrode 7002a to reduce variation in the luminance of the light-emitting display device.

The organic layer 7003a containing a light-emitting substance may be a single layer or a plurality of layers. An example of the structure of the plurality of layers is a structure in which an anode, a hole-injection layer, a hole-transport layer, a light-emitting layer, an electron-transport layer, and an electron-injection layer are stacked. Note that unlike the light-emitting layer, not all these layers are necessarily provided in the organic layer 7003a containing a light-emitting substance. Depending on the need, a layer or layers can be selected as appropriate from these layers except the light-emitting layer, and each layer can be provided in duplicate or more. Specifically, in the organic layer 7003a containing a light-emitting substance, a plurality of light-emitting layers may be overlapped with each other or another hole-injection layer may be overlapped with the electron-injection layer. Further, another component such as an electron-relay layer may be added as appropriate as an intermediate layer, in addition to the charge generation layer.

The light-emitting element 7000a is provided with a partition wall 7009a to cover edges of the first electrode 7001a and a first electrode 7021a of an adjacent pixel. As the partition wall 7009a, an inorganic insulating film or an organic polysiloxane film can be applied in addition to an organic resin film of polyimide, acrylic, polyamide, epoxy, or the like. It is particularly preferable that the partition wall 7009a be formed using a photosensitive resin material so that a side surface of the partition wall 7009a be formed as a tilted surface with a continuous curvature. In the case where a photosensitive resin material is used for the partition wall 7009a, a step of forming a resist mask can be omitted. Further, the partition wall can be formed using an inorganic insulating film. When the inorganic insulating film is used for the partition wall, the amount of moisture contained in the partition wall can be reduced. Even when an inert, electrically conductive film is used for the second electrode, it is preferable to reduce the amount of moisture contained in the partition wall so that a possibility that a hydrogen ion or a hydrogen molecule might be generated due to the use over a long period of time is reduced as much as possible.

Note that heat treatment is performed after the partition is formed. The amount of an impurity including a hydrogen atom remaining in the semiconductor device using the oxide semiconductor is preferably as small as possible. Through the heat treatment, an impurity such as moisture in the partition can be removed.

### (Bottom Emission Structure)

A light-emitting element having a bottom emission structure is described with reference to FIG. 6B. The light-emitting element having a bottom emission structure emits light in a direction indicated by arrows in FIG. 6B.

A pixel, the cross-sectional view of which is given as an example in FIG. 6B, includes a transistor 7401b for driving a light-emitting element and a light-emitting element 7000b. The light-emitting element 7000b includes an organic layer 7003b containing a light-emitting substance between a first electrode 7001b which transmits visible light and a second electrode 7002b, and the first electrode 7001b is electrically connected to a source electrode layer or a drain electrode layer of the transistor 7401b.

The first electrode 7001b is formed using an electrically conductive film which transmits visible light. The material which can be used for the second electrode 7002a in the top emission structure can be used for the electrically conductive film which transmits visible light.

As for the second electrode 7002b, a material which efficiently reflects light emitted from the organic layer 7003b containing a light-emitting substance is preferable, and the material that can be used for the first electrode 7001a in the top emission structure can be used, for example.

Note that one of the first electrode 7001b and the second electrode 7002b functions as an anode, and the other functions as a cathode. It is preferable to use a substance having a high work function for the electrode which functions as an anode, and a substance having a low work function for the electrode which functions as a cathode. Note that in the case where a charge generation layer is provided in contact with the anode, a variety of electrically conductive materials can be used for the anode regardless of their work functions. Specifically, besides a material which has a high work function, a material which has a low work function can also be used. Further, a material having high electrical conductivity is preferably used for each of the first electrode 7001b and the second electrode 7002b to reduce variation in the luminance of the light-emitting display device.

The organic layer 7003b containing a light-emitting substance may be either a single layer or a stack of layers. For the organic layer 7003b containing a light-emitting substance, the structure and material which can be used in FIG. 6A for the organic layer 7003a containing a light-emitting substance can be used.

The light-emitting element 7000b is provided with a partition wall 7009b to cover edges of the first electrode 7001b and a first electrode 7021b of an adjacent pixel. As for the partition wall 7009b, the structure and material which can be used in FIG. 6A for the partition wall 7009a can be used.

### (Dual Emission Structure)

A light-emitting element having a dual emission structure is described with reference to FIG. 6C. The light-emitting element having a dual emission structure emits light in a direction indicated by arrows in FIG. 6C.

A pixel, the cross-sectional view of which is given as an example in FIG. 6C, includes a transistor 7401c for driving a light-emitting element and a light-emitting element 7000c. The light-emitting element 7000c includes an organic layer 7003c containing a light-emitting substance between a first electrode 7001c which transmits visible light and a second electrode 7002c which transmits visible light, and the first electrode 7001c is electrically connected to a source electrode layer or a drain electrode layer of the transistor 7401c.

The first electrode 7001c and the second electrode 7002c are each formed using an electrically conductive film which transmits visible light. The material which can be used for the second electrode 7002a in the top emission structure can be used for the electrically conductive film which transmits visible light.

Note that one of the first electrode 7001c and the second electrode 7002c functions as an anode, and the other functions as a cathode. It is preferable to use a substance having a high work function for the electrode which functions as an anode, and a substance having a low work function for the electrode which functions as a cathode. Note that in the case where a charge generation layer is provided in contact with the anode, a variety of electrically conductive materials can be used for the anode regardless of their work functions. Specifically, besides a material which has a high work function, a material which has a low work function can also be used. Further, a material having high electrical conductivity is preferably used for each of the first electrode 7001c and the second electrode 7002c to reduce the luminance of the light-emitting display device.

The organic layer 7003c containing a light-emitting substance may be either a single layer or a stack of layers. For the organic layer 7003c containing a light-emitting substance, the structure and material which can be used in FIG. 6A for the organic layer 7003a containing a light-emitting substance can be used.

The light-emitting element 7000c is provided with a partition wall 7009c covering edges of the first electrode 7001c and a first electrode 7021c of an adjacent pixel. For the partition wall 7009c, the structure and material which can be used in FIG. 6A for the partition wall 7009a can be used.

Note that the structure of the semiconductor device is not limited to those illustrated in FIGS. 6A to 6C and can be modified in various ways based on techniques disclosed in this specification.

### [Structure of Light-Emitting Device]

Next, the appearance and a cross section of a light-emitting display device (also referred to as a light-emitting display panel) utilizing electroluminescence, which is an example of a semiconductor device, will be described with reference to FIGS. 7A and 7B.

FIG. 7A is a plan view of the light-emitting display device. A thin film transistor and a light-emitting element formed over a first substrate are sealed between a first substrate and a second substrate with a sealant. FIG. 7B is a cross-sectional view taken along a line H-I in FIG. 7A.

A pixel portion 4502, signal line driver circuits 4503a and 4503b, and scan line driver circuits 4504a and 4504b which are provided over a first substrate 4501 are sealed by the sealant 4505 which surrounds the components, together with a filler 4507 between the first substrate 4501 and the second substrate 4506.

A material which has high airtightness and causes little degasification is preferably used for the first substrate 4501 and the second substrate 4506. As the second substrate 4506, a protection film such as a film of plural materials attached or an ultraviolet curable resin film, or a cover material can be used, for example.

A resin can be used for the filler 4507 as well as inert gas such as nitrogen or argon. As examples of the resin which can be used for the filler, PVC (polyvinyl chloride), acrylic, polyimide, an epoxy resin, a silicone resin, PVB (polyvinyl butyral), and EVA (ethylene vinyl acetate) can be given. Alternatively, an ultraviolet curable resin or a thermosetting resin can be used.

Further, the pixel portion 4502, the signal line driver circuits 4503a and 4503b, and the scan line driver circuits 4504a and 4504b formed over the first substrate 4501 each include a plurality of transistors, and it is convenient if all the transistors are formed in the same process.

Structures of the pixel portion 4502 and the signal line driver circuit 4503a in the light-emitting display device will be described using the cross-sectional view in FIG. 7B. Note that a transistor 4510 is an example of the transistors included in the pixel portion 4502 and a transistor 4509 is an example of the transistors included in the signal line driver circuit 4503a.

The transistor 4509 for the driver circuit includes a back-gate electrode 4540 which is positioned over an insulating layer 4544 so as to overlap with a channel formation region of an oxide semiconductor layer. By providing the back-gate electrode 4540 overlapping with the channel formation region of the oxide semiconductor layer, the amount of variation in threshold voltage of the transistor 4509 before and after the BT test (bias-temperature stress test) can be reduced. Note that the back-gate electrode 4540 functions as a second gate electrode layer regardless of whether the potential of the back-gate electrode 4540 is the same as that of a gate electrode layer of the transistor 4509 or not. Alternatively, the potential of the back-gate electrode 4540 may be GND or 0 V, or the back-gate electrode 4540 may be in a floating state.

The insulating layer 4544 is formed to cover the transistor and eliminates unevenness formed by the transistor to make an even surface.

The light-emitting element 4511 includes the organic layer 4512 containing a light-emitting substance between the first electrode 4517 and the second electrode 4513 overlapping with the first electrode 4517. Further, the first electrode 4517 is electrically connected to a source electrode or a drain electrode of the transistor 4510 through an opening formed in the insulating layer 4544.

A partition 4520 has an opening over the first electrode 4517, and is formed to cover an end portion of the first electrode 4517. For the partition 4520, an organic resin film, an inorganic insulating film, or organopolysiloxane can be used. In particular, it is preferable to use a photosensitive material because the sidewall of the opening can become an inclined surface with a continuous curvature.

The organic layer 4512 containing a light-emitting substance may be formed with a single layer or a plurality of layers.

Further, a protective film may be formed over the second electrode 4513 and the partition 4520. The protective film can prevent a phenomenon in which oxygen, hydrogen, moisture, carbon dioxide, or the like enters the light-emitting element 4511. As the protective film, a silicon nitride film, a silicon nitride oxide film, a DLC film, or the like can be used.

A variety of signals and power supply potentials for driving the light-emitting display device are supplied to the signal line driver circuits 4503a and 4503b, the scan line driver circuits 4504a and 4504b, and the pixel portion 4502 via FPCs 4518a and 4518b.

A connection terminal electrode 4515 and the first electrode 4517 are formed through the same process from the same conductive film, and a terminal electrode 4516 and a source and drain electrode layers of the transistor 4509 are formed through the same process from the same conductive film. Note that the connection terminal electrode 4515 and a terminal included in the FPC 4518a are electrically connected to each other through an anisotropic conductive film 4519.

As the substrate positioned in the light extraction direction of the light-emitting element 4511, a substrate that transmits visible light is used. As the visible-light-transmitting substrate, a glass plate, a plastic plate, a polyester film, or an acrylic film can be used, for example.

For example, in the case where the light-emitting element 4511 has a top emission structure or a dual emission structure, a substrate that transmits visible light is used as the second substrate 4506.

Further, the substrate located on the side through which light from the light-emitting element 4511 is extracted can be provided with an optical film as appropriate. As the optical film, a polarizing plate, a circularly polarizing plate (including an elliptically polarizing plate), a retardation plate (a quarter-wave plate or a half-wave plate), or a color filter can be selected and used as appropriate. Further, an antireflection film may be provided. For example, anti-glare treatment by which reflected light can be diffused by projections and depressions on the surface so as to reduce the glare can be performed.

Note that a driver circuit may be formed over a separately prepared substrate and then mounted instead of the signal line driver circuits 4503a and 4503b and the scan line driver circuits 4504a and 4504b of the light-emitting display device given as an example in this embodiment. Only the signal line driver circuits or part thereof, or only the scan line driver circuits or part thereof may be separately formed and mounted; this embodiment is not limited to the structure illustrated in FIGS. 7A and 7B.

Through the above process, a highly reliable light-emitting display device (light-emitting display panel) as a semiconductor device can be manufactured.

In the semiconductor element given as an example in this embodiment, an inert, electrically conductive material is used for the second electrode. Consequently, it is possible to suppress a phenomenon in which moisture that remains in the semiconductor device and/or enters the device from the outside thereof reacts with an electrically conductive material to produce a hydrogen ion or a hydrogen molecule.

Production of a hydrogen ion or a hydrogen molecule which increases the carrier concentration in the oxide semiconductor is suppressed, and accordingly, a semiconductor device having excellent reliability can be provided using the oxide semiconductor. Alternatively, a light-emitting device having excellent reliability can be provided using the oxide semiconductor.

This embodiment can be combined with the structure of any of the other embodiments as appropriate.

### Example 1

### Light-Emitting Display Device 1

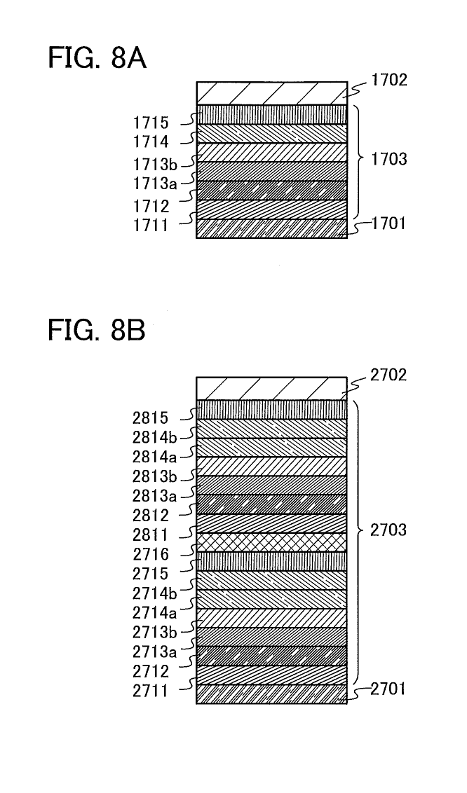

FIG. 8A and Table 1 show structures of the light-emitting elements of the light-emitting display device 1 and a reference display device fabricated in this example.

TABLE 1

| | Light-emitting display | Reference display |
|---|---|---|
| | device 1 | device |
| First electrode | ITSO, 110 nm | |
| Hole-injection layer | NPB:MoOx (=2:0.222), 200 nm | |
| Hole-transport layer | NPB, 10 nm | |
| First light-emitting layer | PCCPA:Rubrene (=1:0.01), 20 nm | |
| Second light-emitting | CzPA:PCBAPA (=1:0.1), 30 nm | |
| layer | | |
| Electron-transport layer | Alq₃, 30 nm | |
| First electron-injection | LiF, 1 nm | |
| layer | | |
| Second electron-injection | Ag:Mg (=0.5:0.05), 5 nm | — |
| layer | | |
| Second electrode | Ag, 100 nm | Al, 200 nm |

The light-emitting display device 1 includes an organic layer 1703 containing a light-emitting substance between a first electrode 1701 and a second electrode 1702 over a substrate (see FIG. 8A).

The organic layer 1703 containing a light-emitting substance in the light-emitting display device 1 has a structure in which a hole-injection layer 1711, a hole-transport layer 1712, a first light-emitting layer 1713a, a second light-emitting layer 1713b, an electron-transport layer 1714, and an electron-injection layer 1715 are sequentially stacked.

Note that as materials of the light-emitting element, indium tin oxide containing silicon oxide (abbreviation: ITSO), 4,4′-bis[N-(1-naphthyl)-N-phenylamino]biphenyl (abbreviation: NPB), molybdenum oxide (MoOx), 9-phenyl-9′-[4-(10-phenyl-9-anthryl)phenyl]-3,3′-bi(9H-carbazole) (abbreviation: PCCPA), rubrene, 9-[4-(N-carbazolyl)]phenyl-10-phenylanthracene (abbreviation: CzPA), 4-(10-phenyl-9-anthryl)-4′-(9-phenyl-9H-carbazol-3-yl)triphenylamine (abbreviation: PCBAPA), tris(8-quinolinolato)aluminum (abbreviation: Alq₃), lithium fluoride (LiF), a silver-magnesium alloy (e.g., AgMg), silver (Ag), and aluminum (Al) were used.

For a second electrode 1702 of the light-emitting display device 1, silver, which has a higher oxidation-reduction potential than the standard hydrogen electrode, was used. Further, the light-emitting element of the light-emitting display device 1 contains alkali metal and/or alkaline earth metal at 2×10¹⁵ atoms/cm² per unit emission area.

Sealing was performed in a glove box under a nitrogen atmosphere so that the light-emitting display device 1 obtained as above was not exposed to the air.

### (Light-Emitting Display Device 2)

A structure of a light-emitting element included in a light-emitting display device 2 is shown in FIG. 8B and Table 2.

TABLE 2

| | Light-emitting display device 2 |
|---|---|
| First electrode | ITSO, 110 nm |
| Hole-injection layer | BPAFLP:MoOx:MoOx (=2:0.25:0.25), |
| | 50 nm |
| Hole-transport layer | BPAFLP, 30 nm |
| First light-emitting layer | PCzPA:SD1 (=1:0.05), 10 nm |
| Second light-emitting layer | CzPA:SD1 (=1:0.05), 25 nm |
| First electron-transport layer | CzPA, 10 nm |
| Second electron-transport layer | BPhen, 15 nm |
| Electron-injection buffer | Ca, 1 nm |
| Electron-relay layer | CuPc, 2 nm |
| Charge generation layer | BPAFLP:MoOx:MoOx (=2:0.25:0.25), |
| | 50 nm |
| Hole-transport layer | PCBA1BP, 10 nm |
| Third light-emitting layer | PCBA1BP:Ir(tppr)₂dpm (=1:0.01), 10 nm |
| Fourth light-emitting layer | DBTBImII:PCBA1BP:Ir(ppy)₃ |
| | (=1:0.1:0.08), 30 nm |
| Third electron-transport layer | DBTBImII, 15 nm |
| Fourth electron-transport layer | BPhen, 15 nm |
| First electron-injection layer | LiF, 1 nm |
| Second electron-injection layer | Ag:Mg, (=0.5:0.05) 5 nm |
| Second electrode | Ag, 100 nm |

The light-emitting element included in the light-emitting display device 2 includes an organic layer 2703 containing a light-emitting substance provided between a first electrode 2701 and a second electrode 2702 over a substrate (see FIG. 8B).

In the light-emitting display device 2, the organic layer 2703 containing a light-emitting substance has a structure in which a hole-injection layer 2711, a hole-transport layer 2712, a first light-emitting layer 2713a, a second light-emitting layer 2713b, a first electron-transport layer 2714a, a second electron-transport layer 2714b, an electron-injection buffer 2715, an electron-relay layer 2716, a charge generation layer 2811, a hole-transport layer 2812, a third light-emitting layer 2813a, a fourth light-emitting layer 2813b, a third electron-transport layer 2814a, a fourth electron-transport layer 2814b, and an electron-injection layer 2815 are sequentially stacked. Note that the electron-injection layer 2815 includes two layers.

In the light-emitting display device 2, silver, which has a higher oxidation-reduction potential than the standard hydrogen electrode, was used for the second electrode 2702. Further, a light-emitting element of the light-emitting display device 2 contains alkali metal and/or alkaline earth metal at 4.5×10¹⁵ atoms/cm² per unit emission area.

Note that as materials of the light-emitting element, indium tin oxide containing silicon oxide (abbreviation: ITSO), molybdenum oxide (MoOx), 4-phenyl-4′-(9-phenylfluoren-9-yl)triphenylamine (abbreviation: BPAFLP), 9-phenyl-3-[4-(10-phenyl-9-anthryl)phenyl]-9H-carbazole (abbreviation: PCzPA), SD1 (product name; manufactured by SFC Co., Ltd), 9-[4-(N-carbazolyl)]phenyl-10-phenylanthracene (abbreviation: CzPA), bathophenanthroline (abbreviation: BPhen), calcium (Ca), copper phthalocyanine (CuPc), 4-phenyl-4′-(9-phenyl-9H-carbazol-3-yl)triphenylamine (abbreviation: PCBA1BP), bis(2,3,5-triphenylpyrazinato)(dipivaloylmethanato)iridium(III) (abbreviation: Ir(tppr)₂(dpm)), 2-[4-(dibenzothiophen-4-yl)phenyl]-1-phenyl-1H-benzimidzole (abbreviation: DBTBIm-II), tris(2-phenylpyridinato-N,C^{2′})iridium(III) (abbreviation: Ir(ppy)₃), lithium fluoride (LiF), a silver-magnesium alloy (e.g., AgMg), and silver (Ag) were used.

Sealing was performed in a glove box under a nitrogen atmosphere so that the light-emitting display device 2 obtained as above was not exposed to the air.

Note that the amount of the alkali metal and/or alkaline earth metal contained in a display region of each of the light-emitting display devices 1 and 2 was in the range of greater than or equal to 4.1×10¹⁴ atoms/cm² and less than or equal to 4.5×10¹⁵ atoms/cm²

### (Reference Display Device)

The structure of the reference display device which is shown in Table 1 was the same as that of the light-emitting display device 1 except for the electron-injection layer and the second electrode 1702. Lithium fluoride was used for the electron-injection layer. Aluminum, which has a lower oxidation-reduction potential than the standard hydrogen electrode, was used for the second electrode 1702. As for the other components in the reference display device, refer to the description of the structure of the light-emitting display device 1.

Sealing was performed in a glove box under a nitrogen atmosphere so that the reference display device obtained as above was not exposed to the air.

### (Evaluation Results)

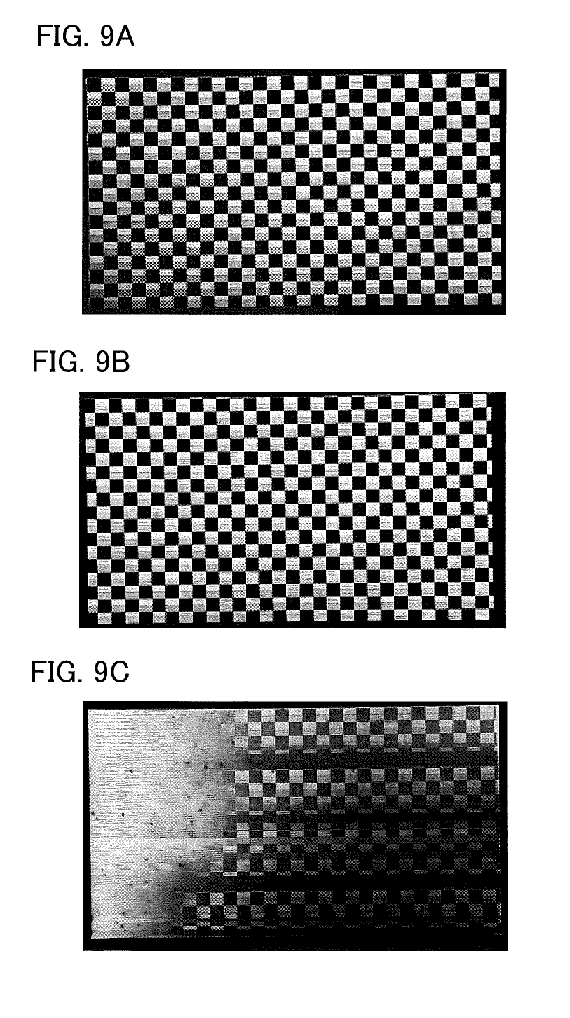

The light-emitting display device 1, the light-emitting display device 2, and the reference display device were preserved under the environment at 80° C. for 15 minutes. After the preservation for 15 minutes, a signal for performing display of a checked pattern (also referred to as checks) in each display device was input, so that display thereof was attempted. The result of display by the light-emitting display device 1 is shown in FIG. 9A, the result of display by the light-emitting display device 2 is shown in FIG. 9B, and the result of display by the reference display device is shown in FIG. 9C.

The light-emitting display devices 1 and 2, in each of which silver (Ag), which has a higher oxidation-reduction potential than the standard hydrogen electrode, was used for the second electrode, operated normally. However, the reference display device, in which aluminum (Al), which has a lower oxidation-reduction potential than the standard hydrogen electrode, was used for the second electrode, did not operate normally.

This application is based on Japanese Patent Application serial No. 2010-203028 filed with the Japan Patent Office on Sep. 10, 2010, the entire contents of which are hereby incorporated by reference.

What is claimed is:

1. A semiconductor device comprising:
a transistor comprising:
a source electrode layer;
a drain electrode layer; and
a channel formation region using an oxide semiconductor; and
a light-emitting element comprising:
a first electrode electrically connected to one of the source electrode layer and the drain electrode layer;
a second electrode over the first electrode; and
an organic layer containing a light-emitting substance interposed between the first electrode and the second electrode,
wherein the second electrode contains a metal having a higher oxidation-reduction potential than a standard hydrogen electrode at an amount greater than or equal to 99 at % and less than 100 at %.

2. The semiconductor device according to claim 1,
wherein the transistor is an enhancement-type transistor.

3. The semiconductor device according to claim 1, further comprising a charge generation layer in contact with the second electrode.

4. The semiconductor device according to claim 1,
wherein the light-emitting element further comprises at least one of an alkali metal and an alkaline earth metal at an amount greater than or equal to 4.1×10¹⁴ atoms/cm² and less than or equal to 4.5×10¹⁵ atoms/cm² per unit emission area.

5. The semiconductor device according to claim 1,
wherein the transistor further comprises:
a gate insulating film;
a gate electrode on one side of the gate insulating film; and
an oxide semiconductor layer on the other side of the gate insulating film, the oxide semiconductor layer comprising the oxide semiconductor,
wherein each of the source electrode layer and the drain electrode layer is in contact with the oxide semiconductor layer and has an end portion overlapped with the gate electrode, and
wherein at least one of the gate electrode and the source electrode layer and the drain electrode layer comprises one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

6. The semiconductor device according to claim 1,
wherein the second electrode is a cathode.

7. A light-emitting device comprising the semiconductor device according to claim 1.

8. A semiconductor device comprising:
a transistor comprising:
a source electrode layer;
a drain electrode layer; and
a channel formation region using an oxide semiconductor; and
a light-emitting element comprising:
a first electrode electrically connected to one of the source electrode layer and the drain electrode layer;
a second electrode over the first electrode; and
an organic layer containing a light-emitting substance interposed between the first electrode and the second electrode,
wherein the second electrode contains an electrically conductive metal oxide having a higher oxidation-reduction potential than a standard hydrogen electrode.

9. The semiconductor device according to claim 8,
wherein the transistor is an enhancement-type transistor.

10. The semiconductor device according to claim 8, further comprising a charge generation layer in contact with the second electrode.

11. The semiconductor device according to claim 8,
wherein the light-emitting element further comprises at least one of an alkali metal and an alkaline earth metal at an amount greater than or equal to 4.1×10¹⁴ atoms/cm² and less than or equal to 4.5×10¹⁵ atoms/cm² per unit emission area.

12. The semiconductor device according to claim 8,
wherein the transistor further comprises:
a gate insulating film;
a gate electrode on one side of the gate insulating film; and
an oxide semiconductor layer on the other side of the gate insulating film, the oxide semiconductor layer comprising the oxide semiconductor,
wherein each of the source electrode layer and the drain electrode layer is in contact with the oxide semiconductor layer and has an end portion overlapped with the gate electrode, and
wherein at least one of the gate electrode and the source electrode layer and the drain electrode layer comprises one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

13. The semiconductor device according to claim 8,
wherein the second electrode is a cathode.

14. A light-emitting device comprising the semiconductor device according to claim 8.

15. A semiconductor device comprising:
a transistor comprising:
a source electrode layer;
a drain electrode layer; and
a channel formation region using an oxide semiconductor; and
a light-emitting element comprising:
a first electrode electrically connected to one of the source electrode layer and the drain electrode layer;
a second electrode over the first electrode; and
an organic layer containing a light-emitting substance interposed between the first electrode and the second electrode,
wherein the second electrode has a stacked-layer structure comprising:
a first layer containing a metal having a higher oxidation-reduction potential than a standard hydrogen electrode at an amount greater than or equal to 99 at % and less than 100 at %; and
a second layer containing an electrically conductive metal oxide having a higher oxidation-reduction potential than the standard hydrogen electrode.

16. The semiconductor device according to claim 15,
wherein the transistor is an enhancement-type transistor.

17. The semiconductor device according to claim 15, further comprising a charge generation layer in contact with the second electrode.

18. The semiconductor device according to claim 15,
wherein the light-emitting element further comprises at least one of an alkali metal and an alkaline earth metal at an amount greater than or equal to 4.1×10¹⁴ atoms/cm² and less than or equal to 4.5×10¹⁵ atoms/cm² per unit emission area.

19. The semiconductor device according to claim 15,
wherein the transistor further comprises:
a gate insulating film;
a gate electrode on one side of the gate insulating film; and
an oxide semiconductor layer on the other side of the gate insulating film, the oxide semiconductor layer comprising the oxide semiconductor,
wherein each of the source electrode layer and the drain electrode layer is in contact with the oxide semiconductor layer and has an end portion overlapped with the gate electrode, and
wherein at least one of the gate electrode and the source electrode layer and the drain electrode layer comprises one or more selected from a metal layer having a higher oxidation-reduction potential than the standard hydrogen electrode, a layer of an alloy of metals each having a higher oxidation-reduction potential than the standard hydrogen electrode, and an electrically conductive metal oxide layer having a higher oxidation-reduction potential than the standard hydrogen electrode.

20. A light-emitting device comprising the semiconductor device according to claim 15.
